(19) United States
(12) Patent Application Publication
(10) Pub. No.: US 2024/0121954 A1
(43) Pub. Date: Apr. 11, 2024

(54) MEMORY DEVICE AND METHOD OF FABRICATING THE SAME

(71) Applicant: MACRONIX International Co., Ltd., Hsinchu (TW)

(72) Inventors: Chih-Wei Hu, Miaoli County (TW); Teng-Hao Yeh, Hsinchu County (TW)

(73) Assignee: MACRONIX International Co., Ltd., Hsinchu (TW)

(21) Appl. No.: 17/963,202

(22) Filed: Oct. 11, 2022

(51) Int. Cl. H01L 27/11582; G11C 16/04; H01L 27/1157

(52) U.S. Cl. CPC H01L 27/11582; G11C 16/0466; H01L 27/1157

(57) ABSTRACT

A memory device includes a first stack structure including first gate layers and first insulating layers alternately stacked with each other. A first channel pillar extends through the first stack structure. A second stack structure is located on the first stack structure and includes second gate layers and second insulating layers alternately stacked with each other. A second channel pillar extends through the second stack structure and is separated from the first channel pillar. A first conductive pillar and a second conductive pillar are located in and electrically connecting with the first channel pillar and the second channel pillar. A charge storage structure is located between the first gate layers and the first channel pillar, and between the second gate layers and the second channel pillar. The memory device may be applied to a 3D AND flash memory.

### BACKGROUND

### Technical Field

The embodiment of the disclosure relates to a semiconductor device and a method of fabricating the same, and particularly, to a memory device and a method of fabricating the same.

### Related Art

Since a non-volatile memory has the advantage that stored data does not disappear at power-off, it becomes a widely used memory for a personal computer or other electronics equipment. Currently, the three-dimensional (3D) memory commonly used in the industry includes a NOR memory and a NAND memory. In addition, another type of 3D memory is an AND memory, which may be applied to a multi-dimensional memory array with high integration and high area utilization, and has an advantage of a fast operation speed. Therefore, the development of a 3D memory device has gradually become the current trend.

### SUMMARY

The disclosure provides a memory device with a plurality of gate layers.

The disclosure provides a method of fabricating a memory device capable of integrating with current processes and reducing an aspect ratio of holes during an etching process to reduce difficulty in the etching process.

An embodiment of the disclosure provides a memory device including a first stack structure, a first channel pillar, a second stack structure, a second channel pillar, a first conductive pillar and a second conductive pillar, and a plurality of charge storage structure. The first stack structure is located above a dielectric substrate and includes a plurality of first conductive layers and a plurality of first insulating layers alternating with each other. The first channel pillar passes through the first stack structure. The second stack structure is located on the first stack structure, and the second stack structure includes a plurality of second conductive layers and a plurality of second insulating layers alternating with each other. The second channel pillar passes through the second stack structure and is separated from the first channel pillar. The first conductive pillar and the second conductive pillar are each electrically connected to the first channel pillar and the second channel pillar. The plurality of charge storage structure is located between the first channel pillar and the first conductive layer and between the second channel pillar and the second conductive layer.

An embodiment of the disclosure provides a memory device including a first stack structure, a second stack structure, a channel pillar, a first conductive pillar and a second conductive pillar, and a charge storage structure. The first stack structure includes a plurality of first conductive layers and a plurality of first insulating layers alternating with each other. The second stack structure is located on the first stack structure, and the second stack structure includes a plurality of second conductive layers and a plurality of second insulating layers alternating with each other. The channel pillar includes a first portion and a second portion. The first portion extends through the first stack structure. The second portion is connected to the first portion and extends through the second stack structure. The first conductive pillar and the second conductive pillar extend through the channel pillar and are electrically connected to the channel pillar. The charge storage structure is located between the channel pillar and the first conductive layer and between the channel pillar and the second conductive layer.

An embodiment of the disclosure provides a method of fabricating a memory device, including the following steps. A first stack structure is formed on a dielectric substrate, and the first stack structure includes a plurality of first intermediate layers and a plurality of first insulating layers alternating with each other. A first opening is formed in the first stack structure. A first channel pillar is formed on a sidewall of the first opening. A first sacrificial pillar and a second sacrificial pillar are formed in the first channel pillar. A second stack structure is formed on the first stack structure, and the second stack structure includes a plurality of second intermediate layers and a plurality of second insulating layers alternating with each other. A second opening is formed in the second stack structure. A second channel pillar is formed in the second opening. An insulating filling layer is formed in the second channel pillar. A first hole and a second hole are formed in the insulating filling layer, and the first hole and the second hole respectively expose the first sacrificial pillar and the second sacrificial pillar. The first sacrificial pillar and the second sacrificial pillar are removed to form a first extending hole and a second extending hole extending through the second stack structure and the first stack structure. A first conductive pillar and a second conductive pillar are formed in the first extending hole and the second extending hole. The plurality of first intermediate layers and the plurality of second intermediate layers are replaced with a plurality of conductive layers. A plurality of charge storage structures are formed between the first channel pillar and the plurality of conductive layers and between the second channel pillar and the plurality of conductive layers.

Based on the above, the memory device of an embodiment of the disclosure includes a plurality of gate layers. The method of fabricating a memory device of an embodiment of the disclosure can be integrated with current processes and reduce an aspect ratio of holes during an etching process to reduce difficulty in the etching process.

### BRIEF DESCRIPTION OF THE DRAWINGS

FIG. 1A shows a circuit diagram of a 3D AND flash memory array according to some embodiments.

FIG. 1B shows a partial perspective view of a part of the memory array in FIG. 1A.

FIG. 1C and FIG. 1D show cross-sectional views taken along line I-I′ of FIG. 1B.

FIG. 1E shows a top view of line II-II′ of FIG. 1B, FIG. 1C, and FIG. 1D.

FIG. 2A to FIG. 2O show schematic cross-sectional views of a process of fabricating a memory device according to an embodiment of the disclosure.

FIG. 3A to FIG. 3F show schematic cross-sectional views of a process of fabricating a memory device with misalignment according to an embodiment of the disclosure.

FIG. 4A to FIG. 4L show schematic cross-sectional views of a process of fabricating a memory device according to another embodiment of the disclosure.

FIG. 5A to FIG. 5G show schematic cross-sectional views of a process of fabricating a memory device with misalignment according to another embodiment of the disclosure.

FIG. 6A, FIG. 6B, FIG. 6C, and FIG. 6D show partial perspective views of FIG. 2O, FIG. 3F, FIG. 4L, and FIG. 5G.

### DESCRIPTION OF THE EMBODIMENTS

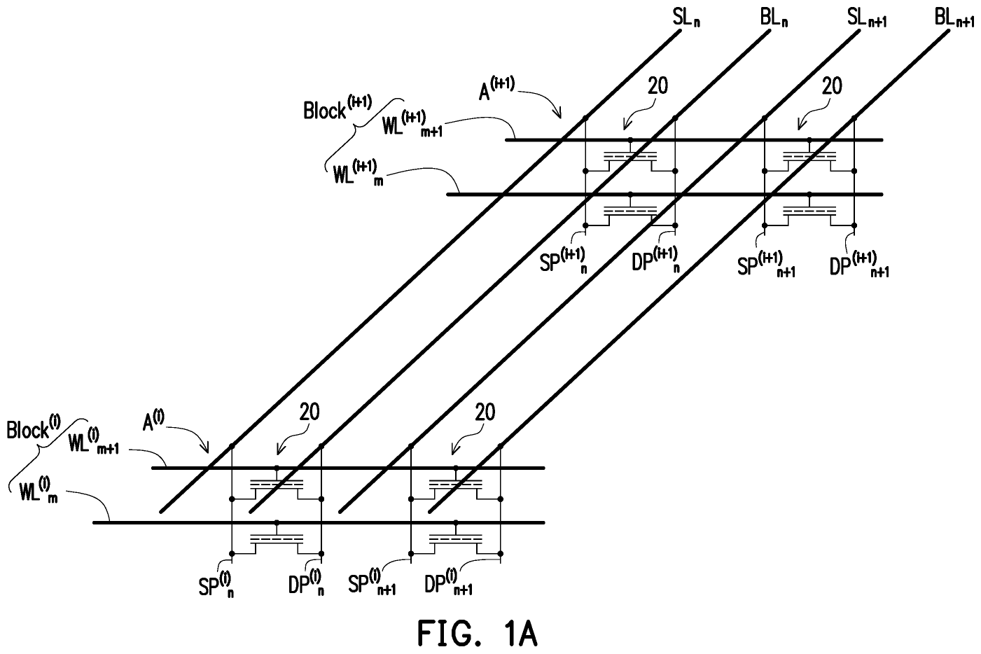

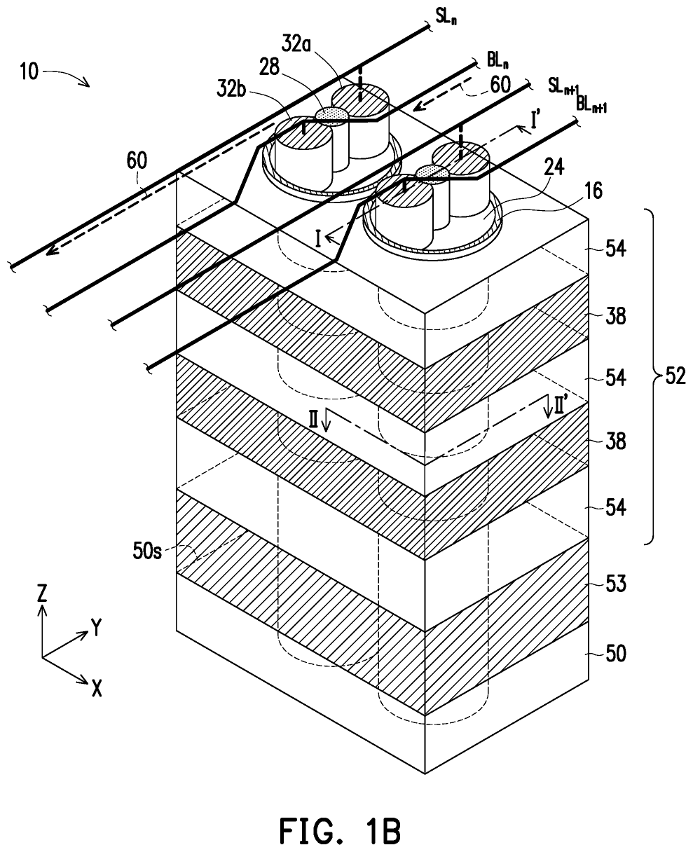

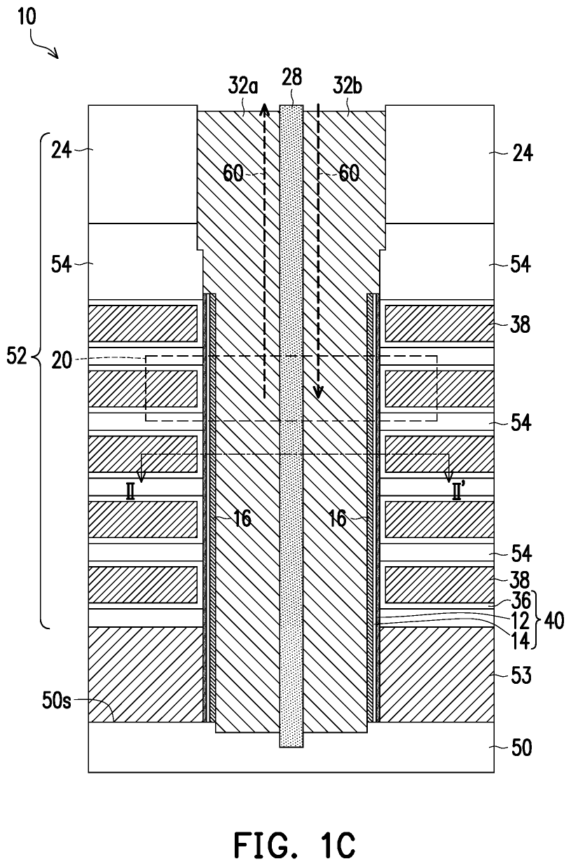

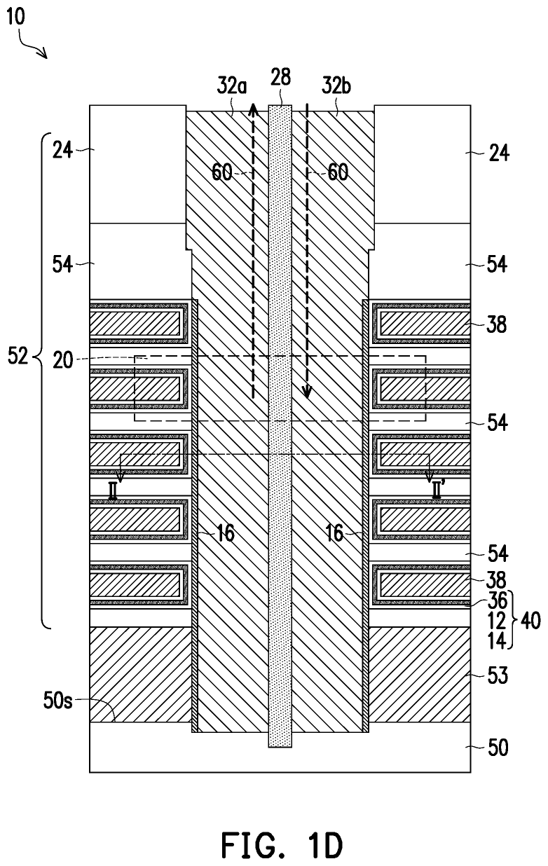

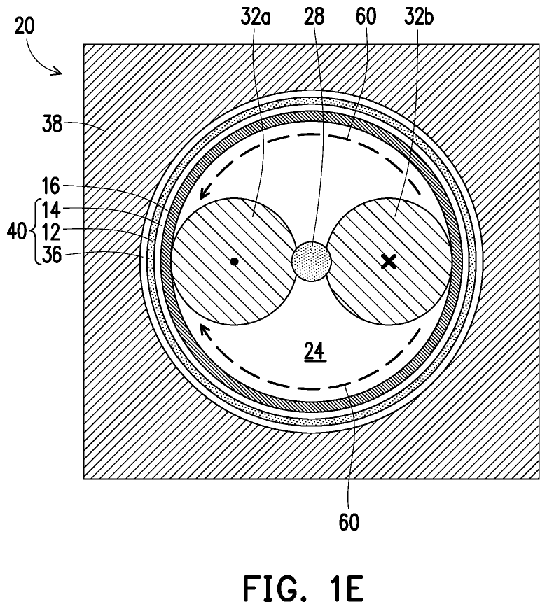

FIG. 1A shows a circuit diagram of a 3D AND flash memory array according to some embodiments. FIG. 1B shows a partial perspective view of a part of the memory array in FIG. 1A. FIG. 1C and FIG. 1D show cross-sectional views taken along line I-I′ of FIG. 1B. FIG. 1E shows a top view of line II-II′ of FIG. 1B, FIG. 1C, and FIG. 1D.

FIG. 1A shows a schematic view of two blocks BLOCK⁽ⁱ⁾ and BLOCK⁽ⁱ⁺¹⁾ of a vertical AND memory array 10 arranged in rows and columns. The block BLOCK⁽ⁱ⁾ includes a memory array A⁽ⁱ⁾. A row (e.g., an (m+1)^{th} row) of the memory array A⁽ⁱ⁾ is a set of AND memory cells 20 having a common word line (e.g., WL⁽ⁱ⁾ₘ₊₁). The AND memory cells 20 of the memory array A⁽ⁱ⁾ in each row (e.g., the (m+1)^{th} row) correspond to a common word line (e.g., WL⁽ⁱ⁾ₘ₊₁) and are coupled to different source pillars (e.g., SP⁽ⁱ⁾ₙ and SP⁽ⁱ⁾n+₁) and drain pillars (e.g., DP⁽ⁱ⁾ₙ and DP⁽ⁱ⁾ₙ₊₁), so that the AND memory cells 20 are logically arranged in a row along the common word line (e.g., WL⁽ⁱ⁾ₘ₊₁).

A column (e.g., an n^{th} column) of the memory array A⁽ⁱ⁾ is a set of AND memory cells 20 having a common source pillar (e.g., SP⁽ⁱ⁾ₙ) and a common drain pillar (e.g., DP⁽ⁱ⁾ₙ). The AND memory cells 20 of the memory array A⁽ⁱ⁾ in each column (e.g., the n^{th} column) correspond to different word lines (e.g., WL⁽ⁱ⁾ₘ₊₁ and WL⁽ⁱ⁾ₘ) and are coupled to a common source pillar (e.g., SP⁽ⁱ⁾ₙ) and a common drain pillar (e.g., DP⁽ⁱ⁾ₙ). Hence, the AND memory cells 20 of the memory array A⁽ⁱ⁾ are logically arranged in a column along the common source pillar (e.g., SP⁽ⁱ⁾ₙ) and the common drain pillar (e.g., DP⁽ⁱ⁾ₙ). In the physical layout, according to the fabrication method as applied, the columns or rows may be twisted and arranged in a honeycomb pattern or other patterns for high density or other reasons.

In FIG. 1A, in the block BLOCK⁽ⁱ⁾, the AND memory cells 20 in the n^{th} column of the memory array A⁽ⁱ⁾ share a common source pillar (e.g., SP⁽ⁱ⁾ₙ) and a common drain pillar (e.g., DP⁽ⁱ⁾ₙ). The AND memory cells 20 in an (n+1)^{th} column share a common source pillar (e.g., SP⁽ⁱ⁾ₙ₊₁) and a common drain pillar (e.g., DP⁽ⁱ⁾ₙ₊₁).

The common source pillar (e.g., SP⁽ⁱ⁾ₙ) is coupled to a common source line (e.g., SLₙ) and the common drain pillar (e.g., DP⁽ⁱ⁾ₙ) is coupled to a common bit line (e.g., BLₙ). The common source pillar (e.g., SP⁽ⁱ⁾ₙ₊₁) is coupled to a common source line (e.g., SLₙ₊₁) and the common drain pillar (e.g., DP⁽ⁱ⁾ₙ₊₁) is coupled to a common bit line (e.g., BLₙ₊₁).

Likewise, the block BLOCK⁽ⁱ⁺¹⁾ includes a memory array A⁽ⁱ⁺¹⁾, which is similar to the memory array A⁽ⁱ⁾ in the block BLOCK⁽ⁱ⁾. A row (e.g., an (m+1)^{th} row) of the memory array A⁽ⁱ⁺¹⁾ is a set of AND memory cells 20 having a common word line (e.g., WL⁽ⁱ⁺¹⁾ₘ₊₁). The AND memory cells 20 of the memory array A⁽ⁱ⁺¹⁾ in each row (e.g., the (m+1)^{th} row) correspond to a common word line (e.g., WL⁽ⁱ⁺¹⁾ₘ₊₁) and are coupled to different source pillars (e.g., SP⁽ⁱ⁺¹⁾ₙ and SP⁽ⁱ⁺¹⁾ₙ₊₁) and drain pillars (e.g., DP⁽ⁱ⁺¹⁾ₙ and DP⁽ⁱ⁺¹⁾ₙ₊₁). A column (e.g., an n^{th} column) of the memory array A⁽ⁱ⁺¹⁾ is a set of AND memory cells 20 having a common source pillar (e.g., SP⁽ⁱ⁺¹⁾ₙ) and a common drain pillar (e.g., DP⁽ⁱ⁺¹⁾ₙ). The AND memory cells 20 of the memory array A⁽ⁱ⁺¹⁾ in each column (e.g., the n^{th} column) correspond to different word lines (e.g., WL⁽ⁱ⁺¹⁾ₘ₊₁ and WL⁽ⁱ⁺¹⁾ₘ) and are coupled to a common source pillar (e.g., SP⁽ⁱ⁺¹⁾ₙ) and a common drain pillar (e.g., DP⁽ⁱ⁺¹⁾ₙ). Hence, the AND memory cells 20 of the memory array A⁽ⁱ⁺¹⁾ are logically arranged in a column along the common source pillar (e.g., SP⁽ⁱ⁺¹⁾ₙ) and the common drain pillar (e.g., DP⁽ⁱ⁺¹⁾ₙ).

The block BLOCK⁽ⁱ⁺¹⁾ and the block BLOCK⁽ⁱ⁾ share source lines (e.g., SLₙ and SLₙ₊₁) and bit lines (e.g., BLₙ and BLₙ₊₁). Therefore, the source line SLₙ and the bit line BLₙ are coupled to the n^{th} column of AND memory cells 20 in the AND memory array A⁽ⁱ⁾ of the block BLOCK⁽ⁱ⁾, and are coupled to the n^{th} column of AND memory cells 20 in the AND memory array A⁽ⁱ⁺¹⁾ of the block BLOCK⁽ⁱ⁺¹⁾. Similarly, the source line SLₙ₊₁ and the bit line BLₙ₊₁ are coupled to the (n+1)^{th} column of AND memory cells 20 in the AND memory array A⁽ⁱ⁾ of the block BLOCK⁽ⁱ⁾, and are coupled to the (n+1)^{th} column of AND memory cells 20 in the AND memory array A⁽ⁱ⁺¹⁾ of the block BLOCK⁽ⁱ⁺¹⁾.

Referring to FIG. 1B to FIG. 1D, the memory array 10 may be disposed over an interconnect structure of a semiconductor die, for example, being disposed on one or more active devices (e.g., transistors) formed on a semiconductor substrate. Therefore, a dielectric substrate 50 is, for example, a dielectric layer (e.g., a silicon oxide layer) over a metal interconnect structure formed on a silicon substrate. The memory array 10 may include a gate stack structure 52, a plurality of channel pillars 16, a plurality of first conductive pillars (also referred to as source pillars) 32a, a plurality of second conductive pillars (also referred to as drain pillars) 32b, and a plurality of charge storage structures 40.

Referring to FIG. 1B, the gate stack structure 52 is formed in an array region and a staircase region (not shown) and extends onto part of the dielectric substrate 50 in a peripheral region. The gate stack structure 52 includes a plurality of gate layers (also referred to as word lines) 38 and a plurality of insulating layer 54 vertically stacked on a surface 50s of the dielectric substrate 50. In a direction Z, the gate layers 38 are electrically isolated from each other by the insulating layer 54 disposed therebetween. The gate layer 38 extends in a direction parallel to the surface of the dielectric substrate 50. The gate layers 38 in the staircase region may have a staircase structure (not shown). Therefore, a lower gate layer 38 is longer than an upper gate layer 38, and the end of the lower gate layer 38 extends laterally beyond the end of the upper gate layer 38. A contact (not shown) for connecting the gate layer 38 may land on the end of the gate layer 38 to connect the gate layers 38 respectively to conductive lines.

Referring to FIG. 1B to FIG. 1D, the memory array 10 further includes a plurality of channel pillars 16. The channel pillar 16 continuously extends through the gate stack structure 52. In some embodiments, the channel pillar 16 may have a ring shape in a top view. The material of the channel pillar 16 may be semiconductor such as undoped polysilicon.

Referring to FIG. 1B to FIG. 1D, the memory array 10 further includes insulating pillars 28, a plurality of first conductive pillars 32a, and a plurality of second conductive pillars 32b. In this example, the first conductive pillars 32a serve as source pillars. The second conductive pillars 32b serve as drain pillars. The first conductive pillar 32a, the second conductive pillar 32b, and the insulating pillar 28 each extend in a direction (i.e., the direction Z) perpendicular to the surface (i.e., the X-Y plane) of the gate layer 38. The first conductive pillar 32a and the second conductive pillar 32b are separated from each other by the insulating pillar 28. The first conductive pillar 32a and the second conductive pillar 32b are electrically connected to the channel pillar 16. The first conductive pillar 32a and the second conductive pillar 32b include doped polysilicon or metal materials. The material of the insulating pillar 28 is, for example, silicon nitride or silicon oxide.

Referring to FIG. 1C and FIG. 1D, the charge storage structure 40 is disposed between the channel pillar 16 and the gate layers 38. The charge storage structure 40 may include a tunneling layer (or referred to as a bandgap engineered tunneling oxide layer) 14, a charge storage layer 12, and a blocking layer 36. The charge storage layer 12 is located between the tunneling layer 14 and the blocking layer 36. In some embodiments, the tunneling layer 14 and the blocking layer 36 include silicon oxide. The charge storage layer 12 includes silicon nitride or other materials capable of trapping charges. In some embodiments, as shown in FIG. 1C, a portion (the tunneling layer 14 and the charge storage layer 12) of the charge storage structure 40 continuously extends in a direction (i.e., the direction Z) perpendicular to the gate layer 38, and the other portion (the blocking layer 36) of the charge storage structure 40 surrounds the gate layer 38. In other embodiments, as shown in FIG. 1D, the charge storage structure 40 (the tunneling layer 14, the charge storage layer 12, and the blocking layer 36) surrounds the gate layer 38.

Referring to FIG. 1E, the charge storage structure 40, the channel pillar 16, the source pillar 32a, and the drain pillar 32b are surrounded by the gate layer 38, and a memory cell 20 is defined. According to different operation methods, a 1-bit operation or a 2-bit operation may be performed on the memory cell 20. For example, when a voltage is applied to the source pillar 32a and the drain pillar 32b, since the source pillar 32a and the drain pillar 32b are connected to the channel pillar 16, electrons may be transferred along the channel pillar 16 and stored in the entire charge storage structure 40. Accordingly, a 1-bit operation may be performed on the memory cell 20. In addition, for an operation involving Fowler-Nordheim tunneling, electrons or holes may be trapped in the charge storage structure 40 between the source pillar 32a and the drain pillar 32b. For an operation involving source side injection, channel-hot-electron injection, or band-to-band tunneling hot carrier injection, electrons or holes may be locally trapped in the charge storage structure 40 adjacent to one of the source pillar 32a and the drain pillar 32b. Accordingly, a single level cell (SLC, 1 bit) or multi-level cell (MLC, greater than or equal to 2 bits) operation may be performed on the memory cell 20.

During operation, a voltage is applied to a selected word line (gate layer) 38; for example, when a voltage higher than a corresponding threshold voltage (Vₜₕ) of the corresponding memory cell 20 is applied, a channel region of the channel pillar 16 intersecting the selected word line 38 is turned on to allow a current to enter the drain pillar 32b from the bit line BLₙ or BLₙ₊₁ (shown in FIG. 1B), flow to the source pillar 32a via the turned-on channel region (e.g., in a direction indicated by arrow 60), and finally flow to the source line SLₙ or SLₙ₊₁ (shown in FIG. 1B).

Referring to FIG. 1C to FIG. 1D, in some embodiments of the disclosure, the channel pillar 16, the source pillar 32a, and the drain pillar 32b further extend through a semiconductor layer 53 between the gate stack structure 52 and the dielectric substrate 50. The semiconductor layer 53 may also be referred to as a dummy gate, which may be used to close a leakage path.

As the number of the gate layers 38 increases continuously, an aspect ratio of the holes of the source pillar 32a and the drain pillar 32b extending through the gate layers 38 increases, which increases the difficulty in etching. In the disclosure, the gate stack structure 52 is formed in multiple parts to reduce the aspect ratio of the holes formed in each part, thereby reducing the difficulty in the etching process.

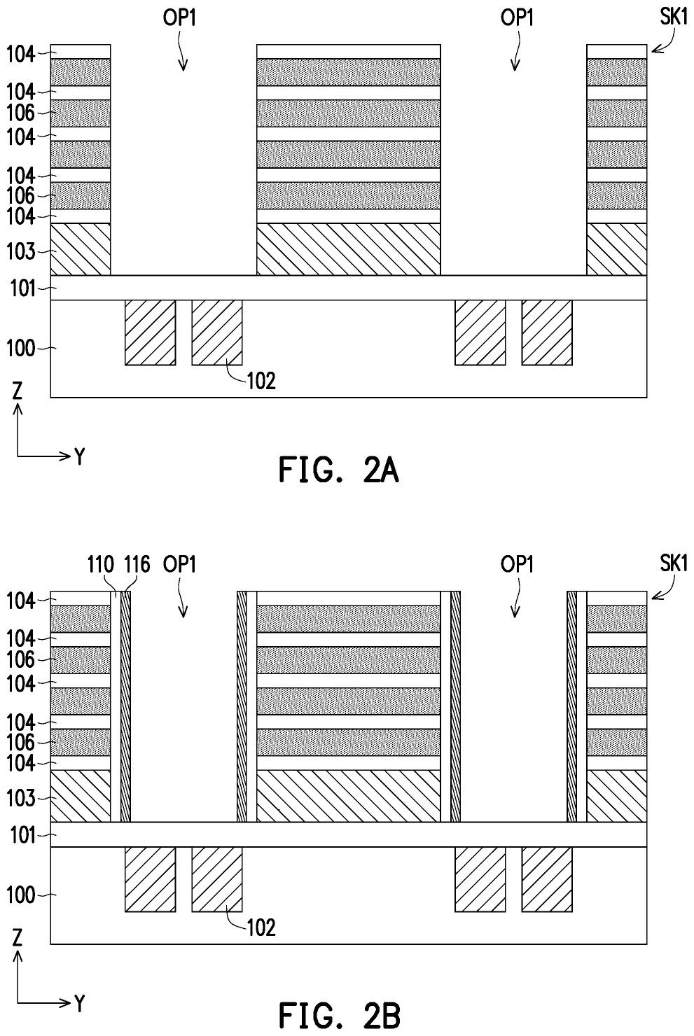

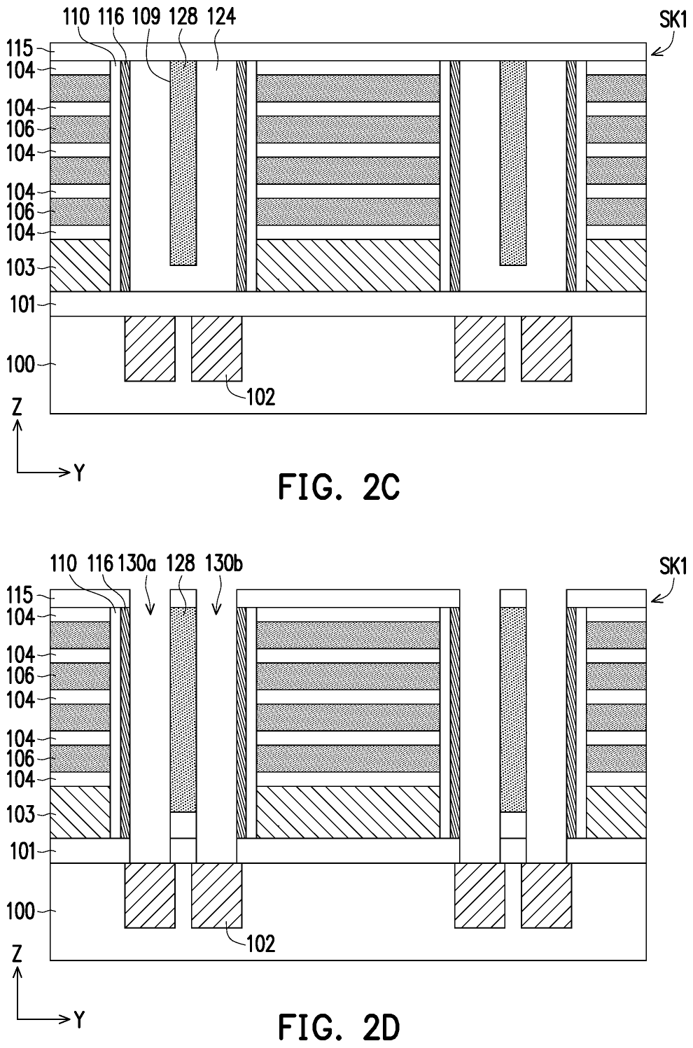

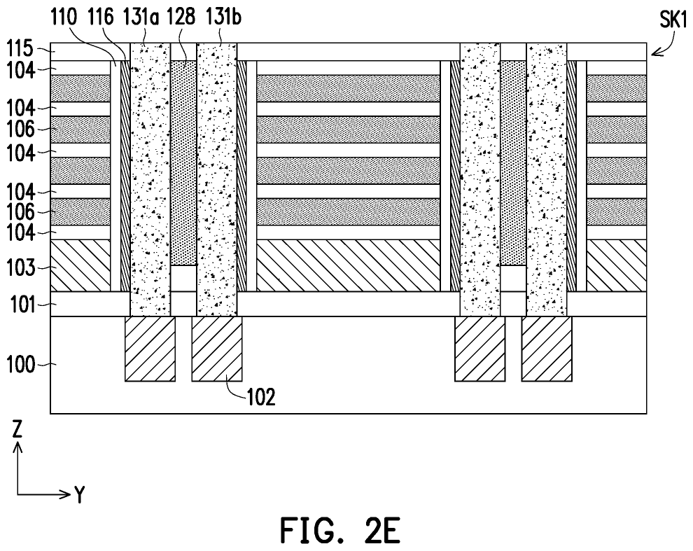

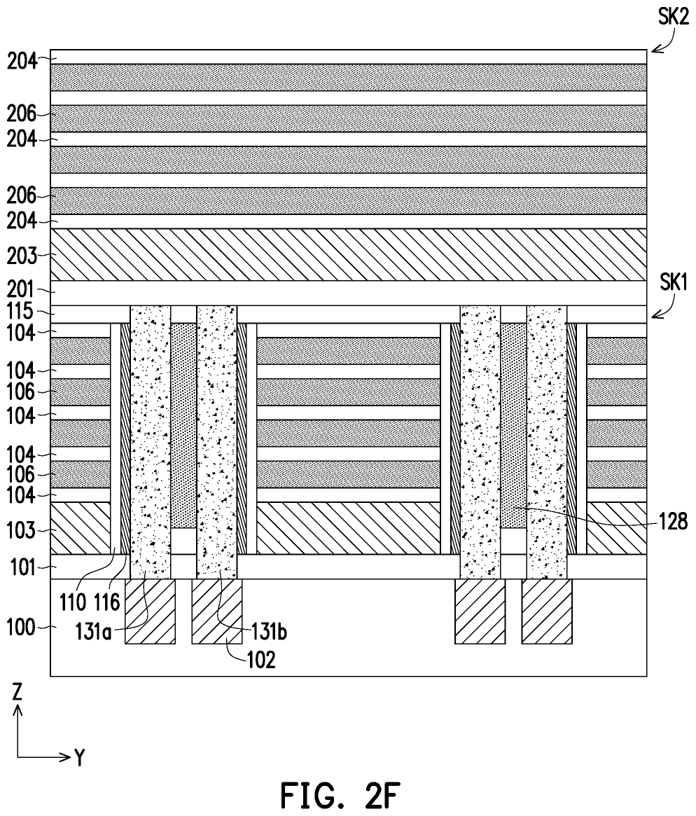

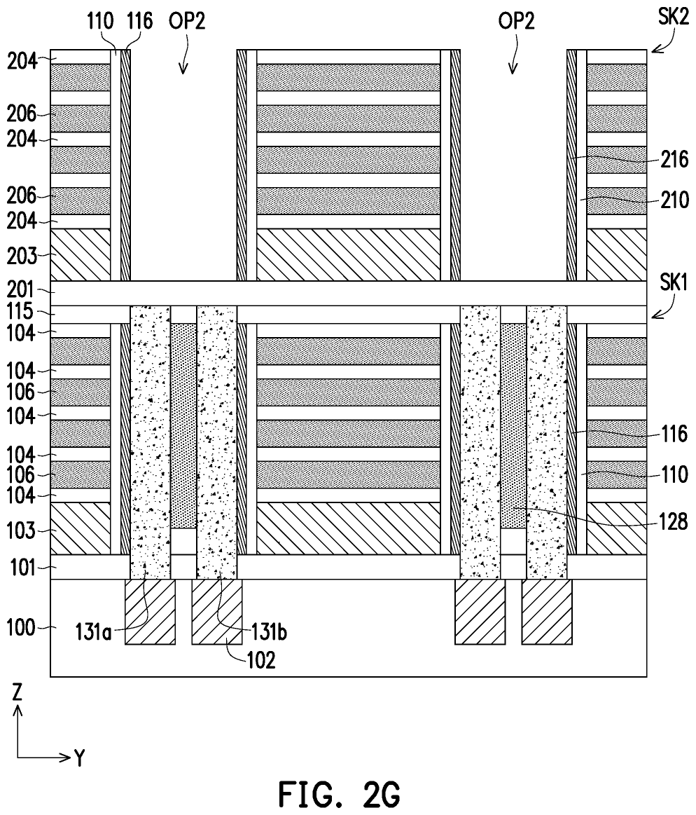

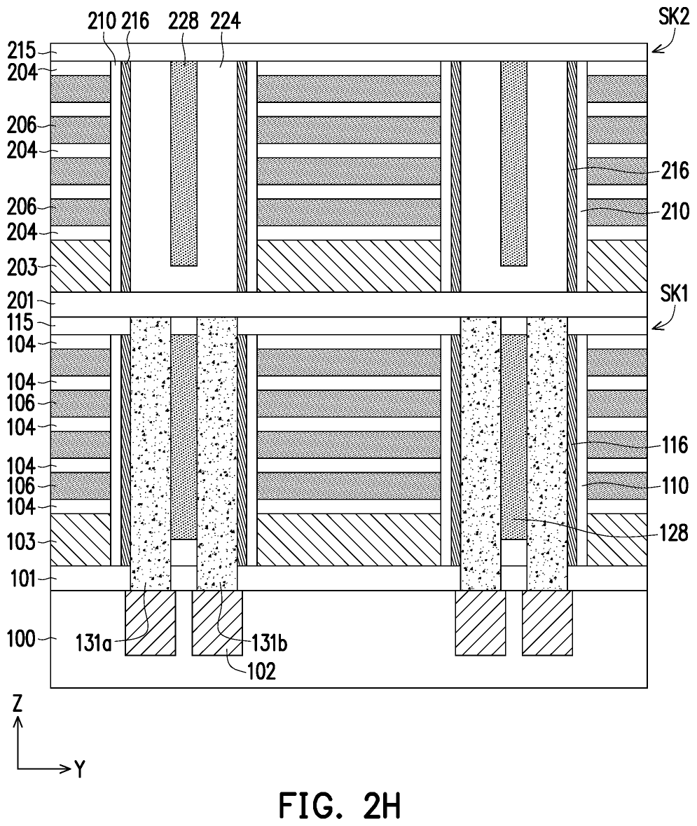

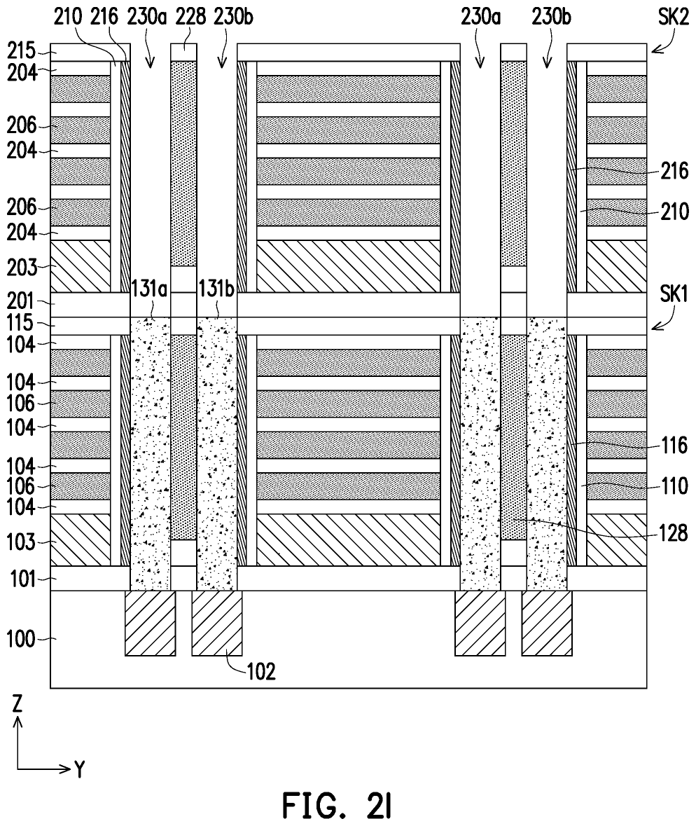

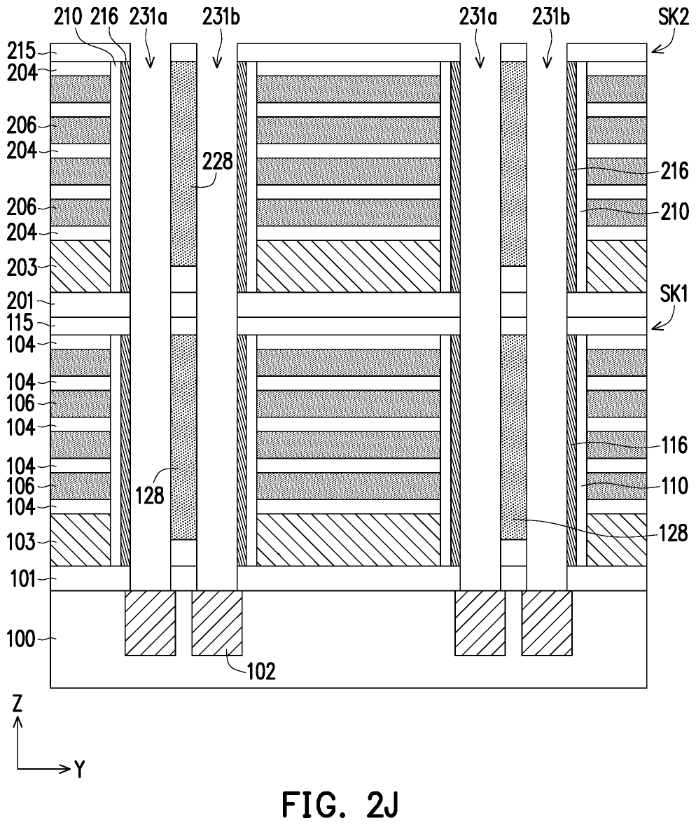

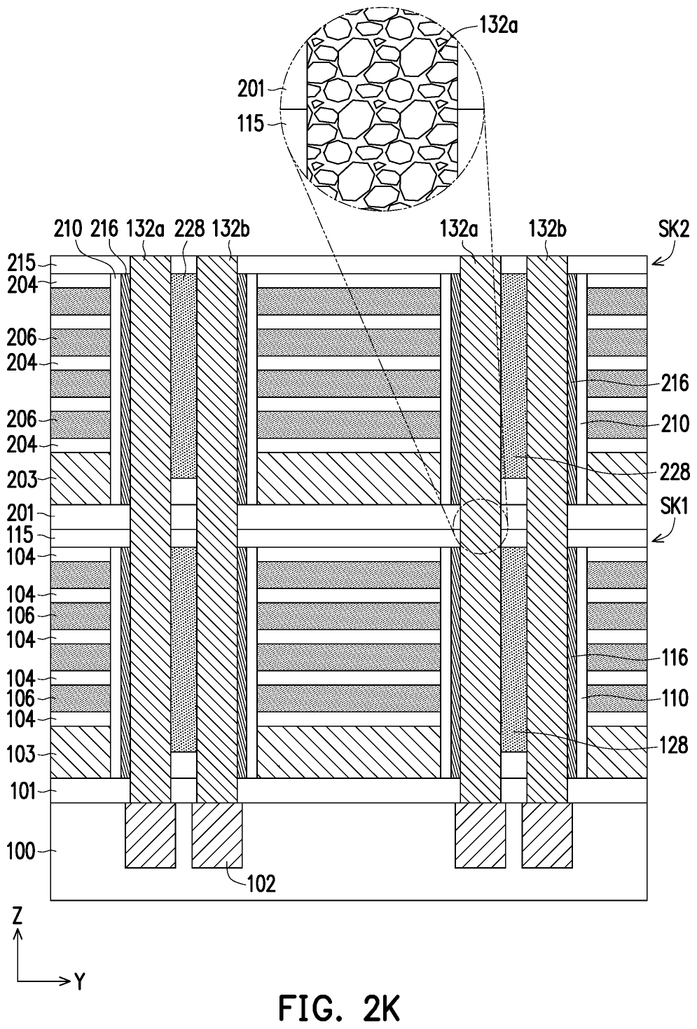

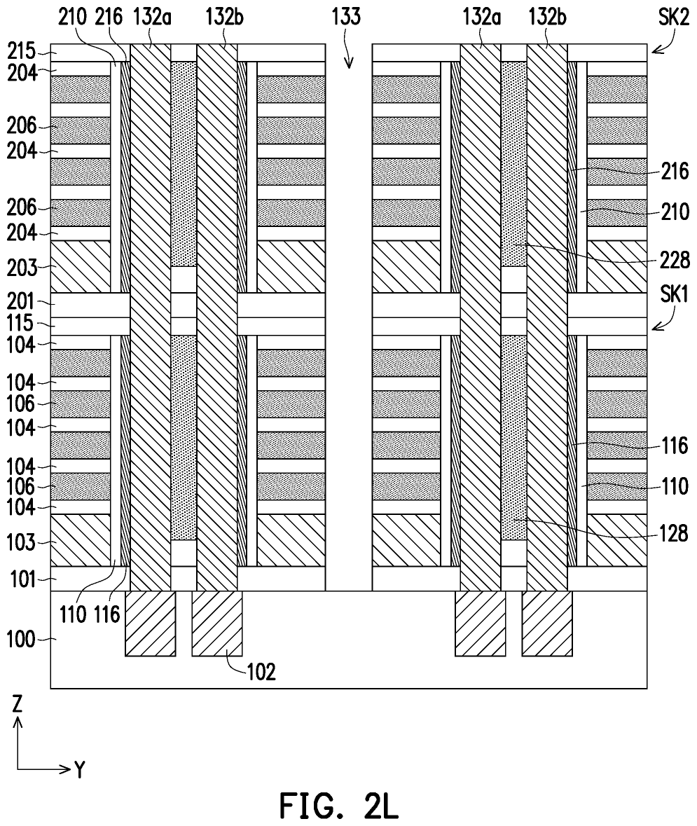

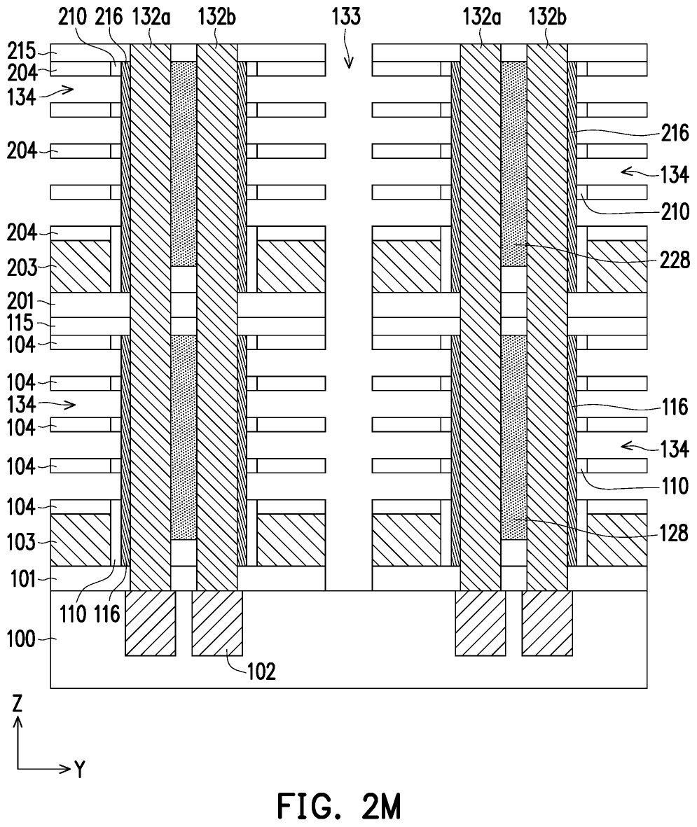

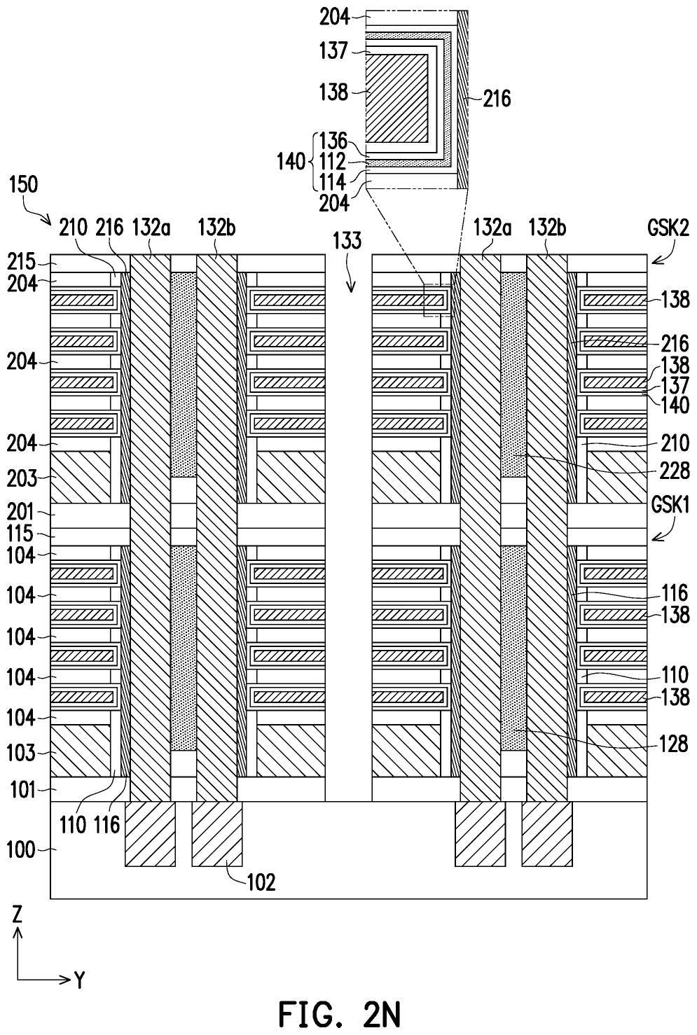

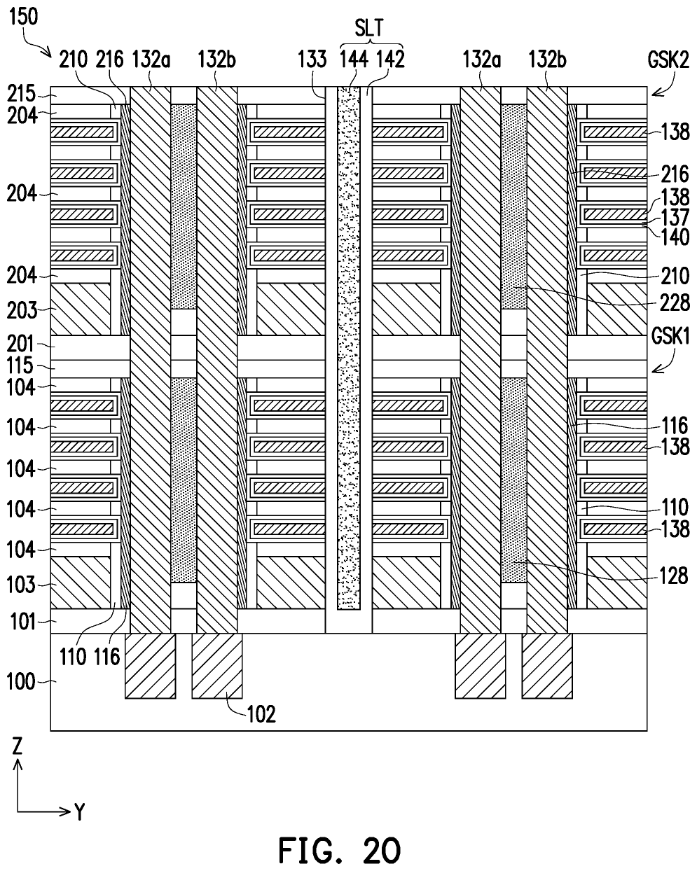

FIG. 2A to FIG. 2O show schematic cross-sectional views of a process of fabricating a memory device according to an embodiment of the disclosure.

Referring to FIG. 2A, a dielectric substrate 100 is provided. The dielectric substrate 100 is, for example, a dielectric layer (e.g., a silicon oxide layer) over a metal interconnect structure formed on a silicon substrate. A stack structure SK1 is formed on the dielectric substrate 100. The stack structure SK1 may also be referred to as an insulating stack structure SK1. In this embodiment, the stack structure SK1 is composed of insulating layers 104 and intermediate layers 106 that are sequentially alternately stacked on the dielectric substrate 100. In other embodiments, the stack structure SK1 may be composed of intermediate layers 106 and insulating layers 104 that are sequentially alternately stacked on the dielectric substrate 100. In addition, in this embodiment, the uppermost layer of the stack structure SK1 is the insulating layer 104. The insulating layer 104 is, for example, a silicon oxide layer. The intermediate layer 106 is, for example, a silicon nitride layer. The intermediate layer 106 may serve as a sacrificial layer which may be partially removed in the subsequent process. In this embodiment, the stack structure SK1 has five insulating layers 104 and four intermediate layers 106, but the disclosure is not limited thereto. In other embodiments, more insulating layers 104 and more intermediate layers 106 may be formed according to the actual requirements.

In some embodiments, before the stack structure SK1 is formed, a stop layer 102 is first formed in the dielectric substrate 100, and an insulating layer 101 and a semiconductor layer 103 are first formed on the dielectric substrate 100. The material of the insulating layer 101 is, for example, silicon oxide. The stop layer 102 is, for example, a conductive pattern such as a polysilicon pattern. The semiconductor layer 103 is, for example, a grounded polysilicon layer. The semiconductor layer 103 may also be referred to as a dummy gate, which may be used to close a leakage path. In some embodiments, the stack structure SK1 may be first patterned to form a staircase structure (not shown) in the staircase region of the dielectric substrate 100.

Next, referring to FIG. 2A, a plurality of openings OP1 are formed in the stack structure SK1 in the array region. In this embodiment, the opening OP1 extends through the semiconductor layer 103, and the bottom surface of the opening OP1 does not expose the stop layer 102, but the disclosure is not limited thereto. In this embodiment, in a top view, the opening OP1 has a circular profile (not shown), but the disclosure is not limited thereto. In other embodiments, the opening OP1 may have a profile of other shapes such as a polygonal shape (not shown).

Referring to FIG. 2B, a protection layer 110 and a channel pillar 116 are formed on a sidewall of the opening OP1. The protection layer 110 is, for example, a silicon oxide layer. The material of the channel pillar 116 may be semiconductor such as undoped polysilicon. The forming method of the protection layer 110 is, for example, thermal oxidation or chemical vapor deposition. The method of forming the channel pillar 116 includes, for example, forming a channel material and a spacer material on the stack structure SK1 and in the opening OP1. Then, an etch-back process is performed to partially remove the channel material and the spacer material to form the channel pillar 116 and a spacer (not shown). The protection layer 110 and the channel pillar 116 cover the sidewall of the opening OP1 and expose the bottom of the opening OP1. The protection layer 110 and the channel pillar 116 may extend through the stack structure SK1 and extend into the insulating layer 101 but are not limited thereto. In a top view, the channel pillar 116 has, for example, a ring shape, and the channel pillar 116 may be continuous in its extending direction (e.g., in a direction perpendicular to the dielectric substrate 100). In other words, the channel pillar 116 is integral in its extending direction and is not divided into multiple disconnected parts. In some embodiments, the channel pillar 116 may have a circular profile in a top view, but the disclosure is not limited thereto. In other embodiments, the channel pillar 116 may also have a profile of other shapes (e.g., a polygonal shape) in a top view. The spacer will be removed in a subsequent process.

Referring to FIG. 2C, an insulating filling material is formed on the stack structure SK1 and filled in the opening OP1. The insulating filling material is, for example, a low-temperature silicon oxide. The insulating filling material filled in the opening OP1 forms an insulating filling layer 124, and a circular seam is left at the center of the insulating filling layer 124. Then, an anisotropic etching process is performed to expand the circular seam to form a hole 109. In this embodiment, the hole 109 extends through the semiconductor layer 103, and the bottom surface of the hole 109 is located between the top surface and the bottom surface of the semiconductor layer 103, but the disclosure is not limited thereto.

Referring to FIG. 2C, an insulating material is formed on the insulating filling layer 124 and in the hole 109. Then, an anisotropic etching process is performed to remove part of the insulating material to form an insulating pillar 128 in the hole 109. The material of the insulating pillar 128 is different from the material of the insulating filling layer 124. The material of the insulating pillar 128 is, for example, silicon nitride. Afterwards, a cap insulating layer 115 is formed on the stack structure SK1. The material of the cap insulating layer 115 is, for example, silicon oxide. The cap insulating layer 115 may be planarized by a planarization process such as a chemical-mechanical polishing process.

Referring to FIG. 2D, a patterning process (e.g., photolithography and etching processes) is performed to form holes 130a and 130b in the cap insulating layer 115 and the insulating filling layer 124. In the etching process, the stop layer 102 may serve as an etch stop layer. Therefore, the formed holes 130a and 130b extend from the stack structure SK1 until the stop layer 102 is exposed. The profiles of the hole patterns defined in the patterning process may be tangent to the profile of the insulating pillar 128 (not shown). The profiles of the hole patterns defined in the patterning process may also exceed the profile of the insulating pillar 128 (not shown). Since the etching rate of the insulating pillar 128 is lower than the etching rate of the insulating filling layer 124, the insulating pillar 128 is hardly damaged by etching and remains.

Referring to FIG. 2E, sacrificial pillars 131a and 131b are formed in the holes 130a and 130b. The material of the sacrificial pillars 131a and 131b is different from the material of the insulating layer 104 and is also different from the material of the intermediate layer 106. The material of the sacrificial pillars 131a and 131b is, for example, a carbon-containing organic material. The carbon-containing organic material may be a polymer such as a photoresist. The photoresist may be a positive photoresist or a negative photoresist. The forming method of the sacrificial pillars 131a and 131b is, for example, a chemical vapor deposition (CVD) method. The material of the sacrificial pillars 131a and 131b is not limited thereto, and another material may also be used.

Referring to FIG. 2F, an insulating layer 201, a semiconductor layer 203, and a stack structure SK2 are formed on the stack structure SK1. The semiconductor layer 203 is, for example, a grounded polysilicon layer. The semiconductor layer 203 may also be referred to as a dummy gate, which may be used to be used as an etching stop layer. The stack structure SK2 may also be referred to as an insulating stack structure SK2. In this embodiment, the stack structure SK2 may be composed of insulating layers 204 and intermediate layers 206 that are sequentially alternately stacked with each other. The materials of the insulating layer 201, the semiconductor layer 203, the insulating layer 204, and the intermediate layer 206 may be the same as or similar to the materials of the insulating layer 101, the semiconductor layer 103, the insulating layer 104, and the intermediate layer 106, respectively.

Referring to FIG. 2G, a patterning process (e.g., lithography and etching processes) is performed to form a plurality of openings OP2 in the stack structure SK2 and the semiconductor layer 203. The bottom of the opening OP2 exposes the insulating layer 201.

Referring to FIG. 2H, a protection layer 210, a channel pillar 216, an insulating filling layer 224, and an insulating pillar 228 are formed in the opening OP2, and a cap insulating layer 215 is formed on the stack structure SK2. The materials and forming methods of the protection layer 210, the channel pillar 216, the insulating filling layer 224, the insulating pillar 228, and the cap insulating layer 215 may be similar to the materials and forming methods of the protection layer 110, the channel pillar 116, the insulating filling layer 124, the insulating pillar 128, and the cap insulating layer 115 and will not be repeatedly described herein.

Referring to FIG. 2I, a patterning process (e.g., lithography and etching processes) is performed to form holes 230a and 230b extending through the cap insulating layer 215 and the insulating filling layer 224. During the etching process, the sacrificial pillars 131a and 131b may serve as etch stop layers. Therefore, the formed holes 230a and 230b extend from the stack structure SK2 until the sacrificial pillars 131a and 131b are exposed.

Referring to FIG. 2J, the sacrificial pillars 131a and 131b are removed so that the holes 230a and 230b respectively communicate with the holes 130a and 130b to form extending holes 231a and 231b. The extending holes 231a and 231b extend from the stack structure SK2 through the stack structure SK1 until the stop layer 102 is exposed. The method of removing the sacrificial pillars 131a and 131b may be a dry removal method or a wet removal method. When the material of the sacrificial pillars 131a and 131b is a carbon-containing organic material, a dry removal method such as an oxygen plasma ashing method may be adopted to completely remove the sacrificial pillars 131a and 131b without issues such as over-etching or an insufficient etching depth of the holes.

Referring to FIG. 2K, conductive pillars 132a and 132b are formed in the extending holes 231a and 231b. The conductive pillars 132a and 132b may respectively serve as a source pillar and a drain pillar to be each electrically connected to the channel pillars 216 and 116. The conductive pillars 132a and 132b may be formed by, for example, forming a conductive material on the dielectric substrate 100 and in the extending holes 231a and 231b, and then performing an etch-back process. The material of the conductive pillars 132a and 132b is, for example, doped polysilicon.

The conductive pillars 132a and 132b continuously extend through the cap insulating layer 215, the stack structure SK2, the semiconductor layer 203, the insulating layer 201, the cap insulating layer 115, the stack structure SK1, and the semiconductor layer 103. Complete crystal grains are present in the conductive pillars 132a and 132b between the insulating layer 201 below the stack structure SK2 and the cap insulating layer 115 above the stack structure SK1, and there is no planar interface formed with etched or polished crystal grains.

Referring to FIG. 2L, a patterning process (e.g., lithography and etching processes) is performed on the cap insulating layer 215, the stack structure SK2, the semiconductor layer 203, the insulating layer 201, the cap insulating layer 115, the stack structure SK1, and the semiconductor layer 103 to form a slit trench 133.

Referring to FIG. 2M to FIG. 2N, a partial replacement process is performed on the intermediate layers 206 and 106. First, referring to FIG. 2M, an etching process such as a wet etching process is performed to remove the intermediate layers 206 and 106 surrounding the slit trench 133. An etching solution (e.g., hot phosphoric acid) used in the etching process is injected into the slit trench 133, and then the contacted portions of the intermediate layers 206 and 106 are removed. When the intermediate layers 206 and 106 between the channel pillars 216 and 116 and the slit trench 133 are removed, since the material of the protection layers 210 and 110 is different from the material of the intermediate layers 206 and 106, the protection layers 210 and 110 may serve as etch stop layers to protect the channel pillars 216 and 116. The etching process is continued, and through time mode control, most of the intermediate layers 206 and 106 are removed to form a plurality of horizontal openings 134. The protection layers 210 and 110 on the sidewalls of the intermediate layers 206 and 106 may be removed during the etching process.

Referring to FIG. 2N, a plurality of tunneling layers 114, a plurality of charge storage layers 112, a plurality of blocking layers 136, and a plurality of gate layers (also referred to as conductive layers) 138 are formed in the horizontal openings 134. The material of the tunneling layer 114 is, for example, silicon oxide. The material of the charge storage layer 112 is, for example, silicon nitride. The material of the blocking layer 136 is, for example, silicon oxide or a high dielectric constant material having a dielectric constant greater than or equal to 7, such as aluminum oxide (Al₁O₃), hafnium oxide (HfO₂), lanthanum oxide (La₂O₅), transition metal oxide, lanthanide oxide, or combinations thereof. The material of the gate layer 138 is, for example, tungsten. In some embodiments, before the gate layers 138 are formed, barrier layers 137 are formed. The material of the barrier layer 137 is, for example, titanium (Ti), titanium nitride (TiN), tantalum (Ta), tantalum nitride (TaN), or a combination thereof.

The method of forming the tunneling layer 114, the charge storage layer 112, the blocking layer 136, the barrier layer 137, and the gate layer 138 includes, for example, sequentially forming a tunneling material, a charge storage material, a blocking material, a barrier material, and a conductive material in the slit trench 133 and the horizontal openings 134. Then, an etch-back process is performed to form the tunneling layer 114, the charge storage layer 112, the blocking layer 136, the barrier layer 137, and the gate layer 138 in the horizontal openings 134. In some embodiment, the tunneling material, the charge storage material, the blocking material, the barrier material, and the conductive material in the slit trenches 133 are all removed. The tunneling layer 114, the charge storage layer 112, and the blocking layer 136 are collectively referred to as a charge storage structure 140. Adjacent charge storage structures 140 are separated by the protective layers 210 and 110.

In other embodiments, the barrier material and the conductive material in the slit trenches 133 are removed, and the tunneling material, the charge storage material, and the blocking material are retained (not shown), so that the tunneling layer 114, the charge storage layer 112, and the blocking layer 136 continuously extend from the horizontal openings 134 to the slit trenches 133.

At this time, a gate stack structure 150 is formed. The gate stack structure 150 includes stack structures GSK1 and GSK2. The stack structure GSK1 is located on the dielectric substrate 100 and surrounds the channel pillars 116. The stack structure GSK2 is located on the stack structure GSK1 and surrounds the channel pillars 216. The stack structure GSK1 includes a plurality of gate layers 138 and a plurality of insulating layers 104 that are alternately stacked with each other. The stack structure GSK2 includes a plurality of gate layers 138 and a plurality of insulating layers 204 that are alternately stacked with each other.

Referring to FIG. 2N and FIG. 2O, a slit SLT is formed in the slit trench 133. The method of forming the slit SLT includes filling an insulating liner material and a conductive material on the gate stack structure 150 and in the slit trench 133. The insulating liner material is, for example, silicon oxide. The conductive material is, for example, polysilicon. Then, the excessive insulating liner material and conductive material on the gate stack structure 150 are removed by an etch-back process or a planarization process to form a liner layer 142 and a conductive layer 144. The liner layer 142 and the conductive layer 144 are collectively referred to as a slit SLT. In other embodiments, the slit SLT may also be completely filled with an insulating material without any conductive layer. In still other embodiments, the slit SLT may also be a liner layer 142, and the liner layer 142 covers an air gap without any conductive layer.

Afterwards, a contact (not shown) is formed in the staircase region. The contact lands on the end of the gate layer 138 in the staircase region and is electrically connected thereto.

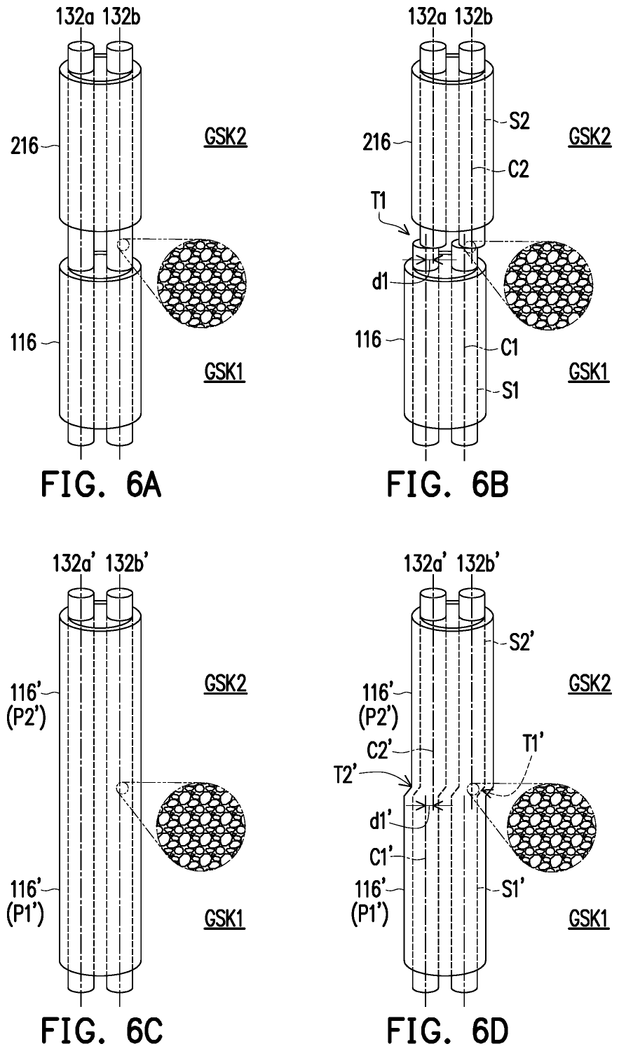

FIG. 6A shows a partial perspective view of FIG. 2O.

Referring to FIG. 2O and FIG. 6A, the memory device of the disclosure includes the stack structures GSK1 and GSK2, the channel pillars 116 and 216, the conductive pillars 132a and 132b, and the charge storage structure 140. The stack structure GSK1 is located above the dielectric substrate 100 and includes a plurality of conductive layers 138 and a plurality of insulating layers 104 alternating with each other. The stack structure GSK2 is located on the stack structure GSK1, and the stack structure GSK2 includes a plurality of conductive layers 138 and a plurality of insulating layers 204 alternating with each other. The channel pillar 116 passes through the stack structure GSK1. The channel pillar 216 passes through the stack structure GSK2 and is separated from the channel pillar 116. The charge storage structure 140 includes the charge storage layer 112. The charge storage layer 112 is located between the channel pillar 216 and the conductive layer 138 and between the channel pillar 116 and the conductive layer 138.

In this embodiment, the opening OP2 (shown in FIG. 2G) is exactly aligned with the opening OP1 (shown in FIG. 2B), and the holes 230a and 230b (shown in FIG. 2I) are exactly aligned with the holes 130a and 130b (shown in FIG. 2D), respectively. Therefore, the channel pillar 216 is located directly above the channel pillar 116 and overlaps the channel pillar 116. The sidewalls of the conductive pillars 132a and 132b around the stack structure GSK2 are substantially aligned with the sidewalls of the conductive pillars 132a and 132b around the stack structure GSK1.

Referring to FIG. 6A, the conductive pillars 132a and 132b are continuous pillars which continuously extend through the channel pillars 216 and 116 and are electrically connected to the channel pillars 216 and 116. Moreover, complete crystal grains are present between the conductive pillars 132a and 132b outside the channel pillar 216 and the conductive pillars 132a and 132b outside the channel pillar 116, and there is no planar interface formed with etched or polished crystal grains.

Referring to FIG. 2N, the memory device of the disclosure further includes the insulating pillars 128 and 228 which are respectively located between the conductive pillars 132a and 132b. The insulating pillar 228 is located above the insulating pillar 128 and completely overlaps the insulating pillar 128.

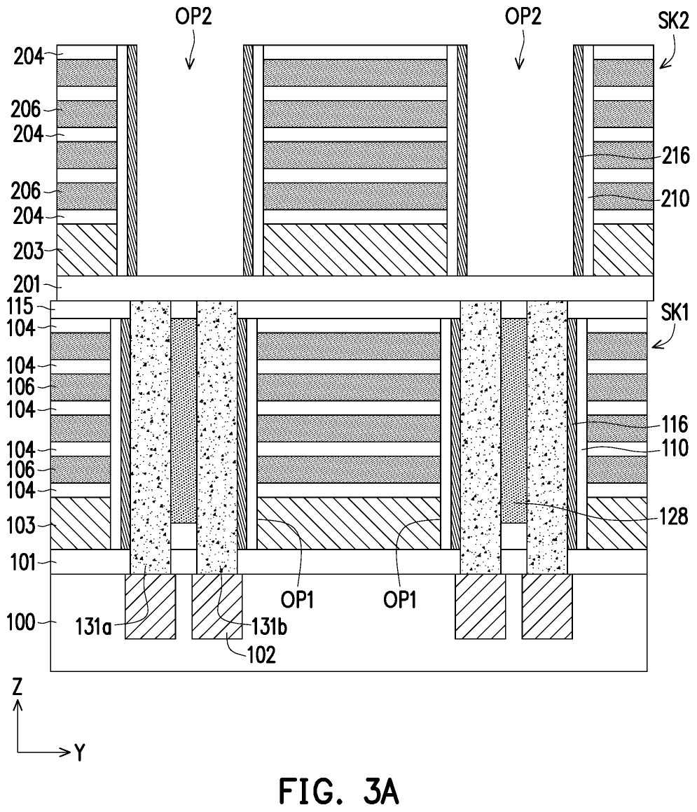

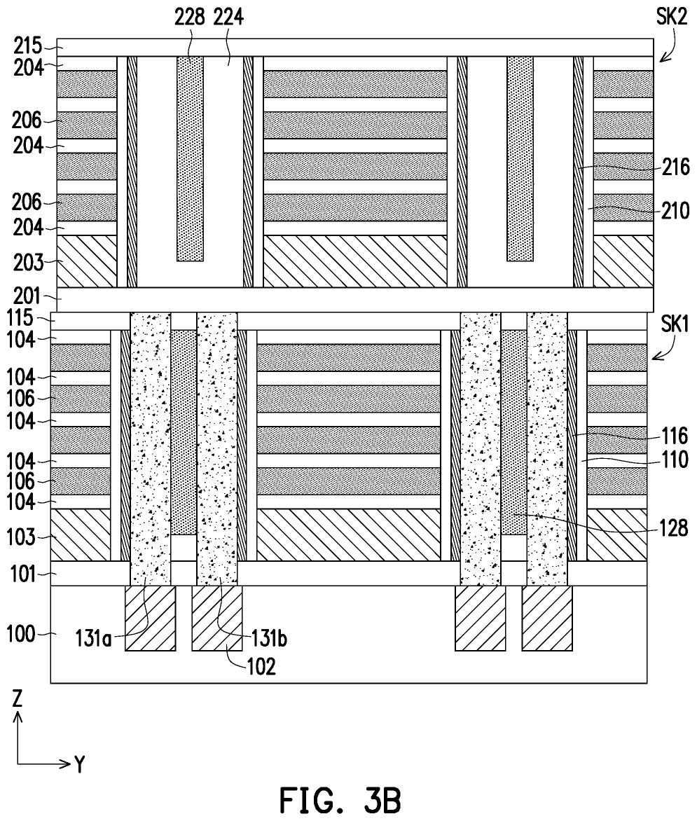

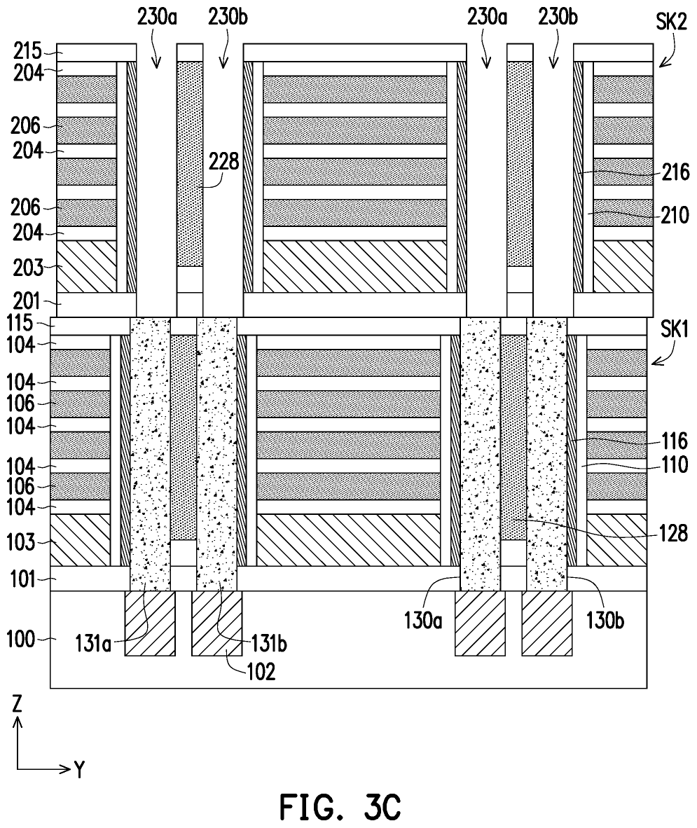

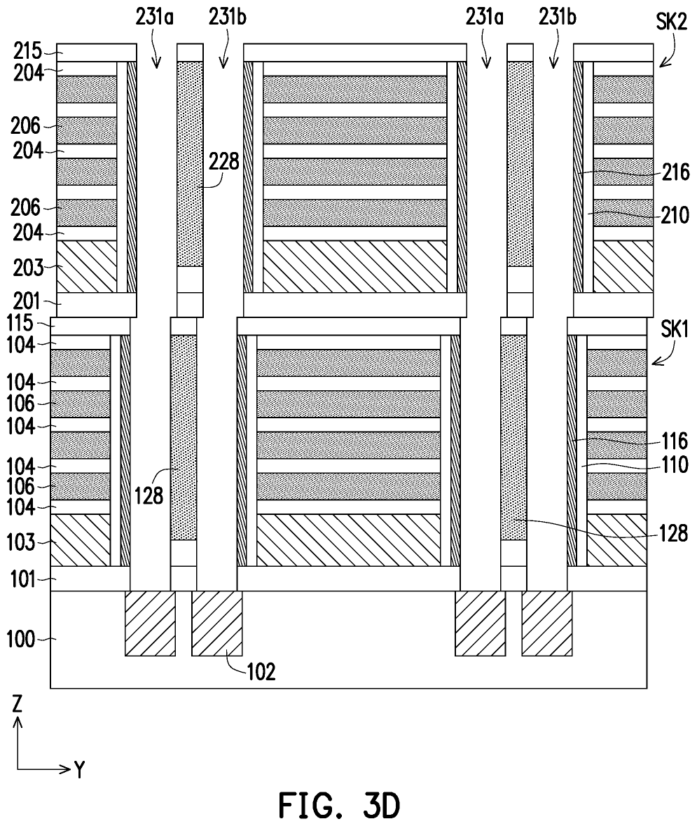

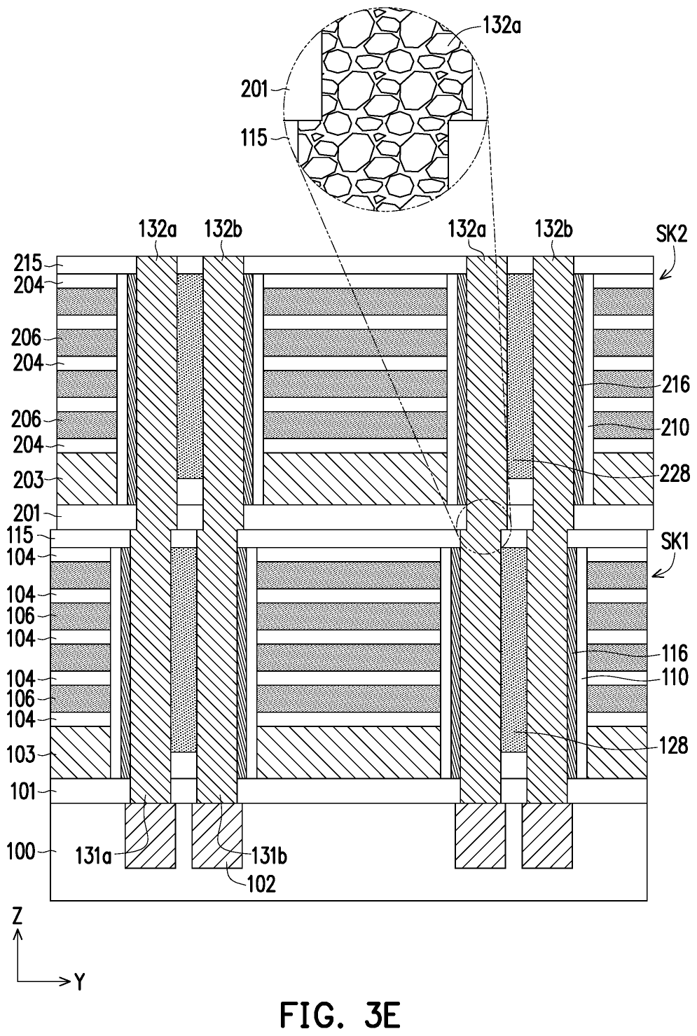

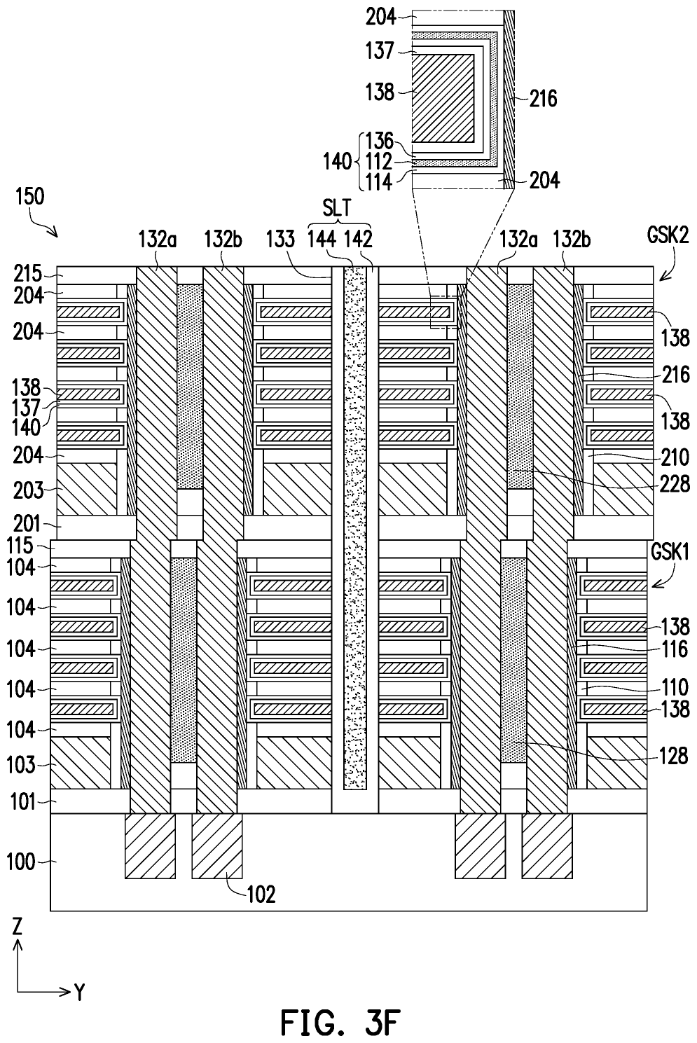

FIG. 3A to FIG. 3F show schematic cross-sectional views of a process of fabricating a memory device with misalignment according to an embodiment of the disclosure.

Referring to FIG. 3A to FIG. 3D, in some cases, misalignment occurs when the opening OP2 is formed (as shown in FIG. 3A), or misalignment occurs when the holes 230a and 230b are subsequently formed; as a result, the holes 230a and 230b are not completely aligned with the sacrificial pillars 131a and 131b (as shown in FIG. 3C). Therefore, the sacrificial pillars 131a and 131b are not completely exposed by the holes 230a and 230b. However, since the sacrificial pillars 131a and 131b may be easily removed by the oxygen plasma ashing method, the sacrificial pillars 131a and 131b can be completely removed to form the extending holes 231a and 231b extending through the stack structures SK2 and SK1 (as shown in FIG. 3D). Therefore, it is possible to avoid issues such as incomplete or excessive etching of the extending holes 231a and 231b.

Referring to FIG. 3E, in the disclosure, the stack structure SK2 is formed separately from the stack structure SK1, but the conductive pillars 132a and 132b are simultaneously formed in the extending holes 231a and 231b. The conductive pillars 132a and 132b may continuously extend through the stack structures SK2 and SK1. Complete crystal grains are present in the conductive pillars 132a and 132b between the insulating layer 201 below the stack structure SK2 and the cap insulating layer 115 above the stack structure SK1, and there is no planar interface formed with etched or polished crystal grains.

Referring to FIG. 3F, subsequently, a partial replacement process may be performed according to the above process to replace the intermediate layers 206 and 106 with a plurality of tunneling layers 114, a plurality of charge storage layers 112, a plurality of blocking layers 136, and a plurality of gate layers 138. Afterwards, the slit SLT is formed.

FIG. 6B shows a partial perspective view of FIG. 3F.

Referring to FIG. 3F and FIG. 6B, the memory device of the disclosure includes the stack structures GSK1 and GSK2, the channel pillars 116 and 216, the conductive pillars 132a and 132b, and the charge storage structure 140. The stack structure GSK1 is located above the dielectric substrate 100 and includes a plurality of conductive layers 138 and a plurality of insulating layers 104 alternating with each other. The stack structure GSK2 is located on the stack structure GSK1. The stack structure GSK2 includes a plurality of conductive layers 138 and a plurality of insulating layers 204 alternating with each other. The channel pillar 116 passes through the stack structure GSK1. The channel pillar 216 passes through the stack structure GSK2 and is separated from the channel pillar 116. The charge storage structure 140 includes the charge storage layer 112. The charge storage layer 112 is located between the channel pillar 216 and the conductive layer 138 and between the channel pillar 116 and the conductive layer 138.

In this embodiment, the opening OP2 is not completely aligned with the opening OP1 (as shown in FIG. 3A), and the holes 230a and 230b are not completely aligned with the holes 130a and 130b, respectively.

Since the opening OP2 is not completely aligned with the opening OP1, the channel pillar 216 is located above the channel pillar 116 and is partially overlapping and partially non-overlapping with the channel pillar 116.

Since the holes 230a and 230b are not completely aligned with the holes 130a and 130b, respectively, the conductive pillars 132a and 132b are each divided into two segments S1 and S2. The segment S1 is surrounded by the stack structure GSK1, and the segment S2 is surrounded by the stack structure GSK2. The segment S2 is partially overlapping and partially non-overlapping with the segment S1. In other words, a centerline C2 of the segment S2 is not aligned with a centerline C1 of the segment S1, and a non-zero distance d1 is present therebetween. The sidewall of the segment S2 is not aligned with the sidewall of the segment S1 and thus a turning T1 is present.

Although the conductive pillars 132a and 132b include the segments S1 and S2, the conductive pillars 132a and 132b are continuous pillars which continuously extend through the channel pillars 216 and 116 and are electrically connected to the channel pillars 216 and 116. In addition, complete crystal grains are present between the segments S1 and S2, and there is no planar interface formed with etched or polished crystal grains.

Referring to FIG. 3F, the memory device of the disclosure further includes the insulating pillars 128 and 228 which are respectively located between the conductive pillars 132a and 132b. The insulating pillar 228 is located above the insulating pillar 128 and is partially overlapping and partially non-overlapping with the insulating pillar 128.

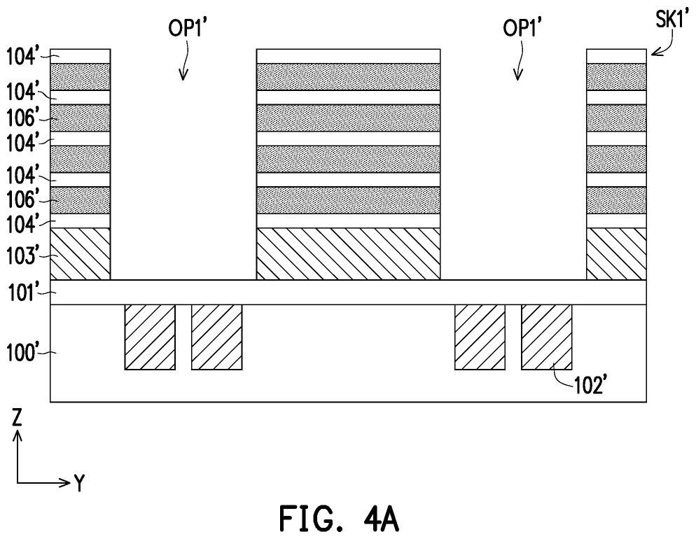

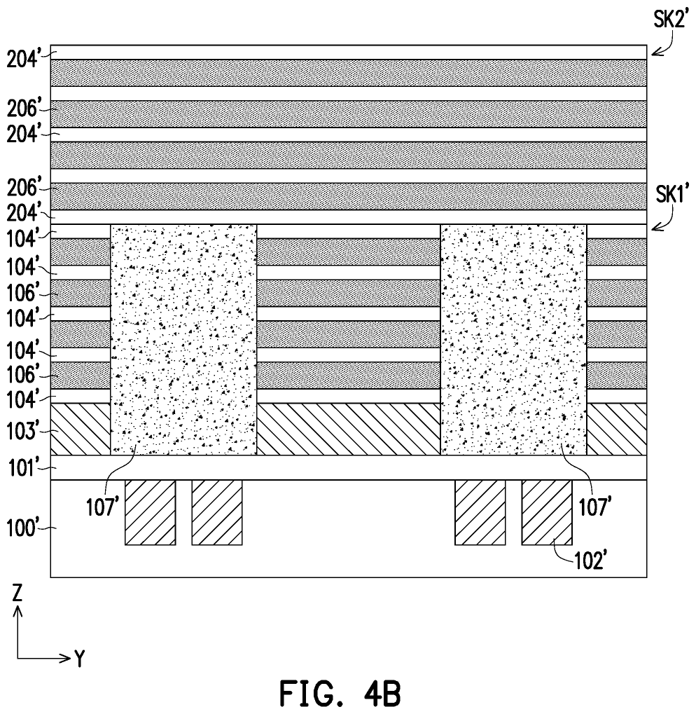

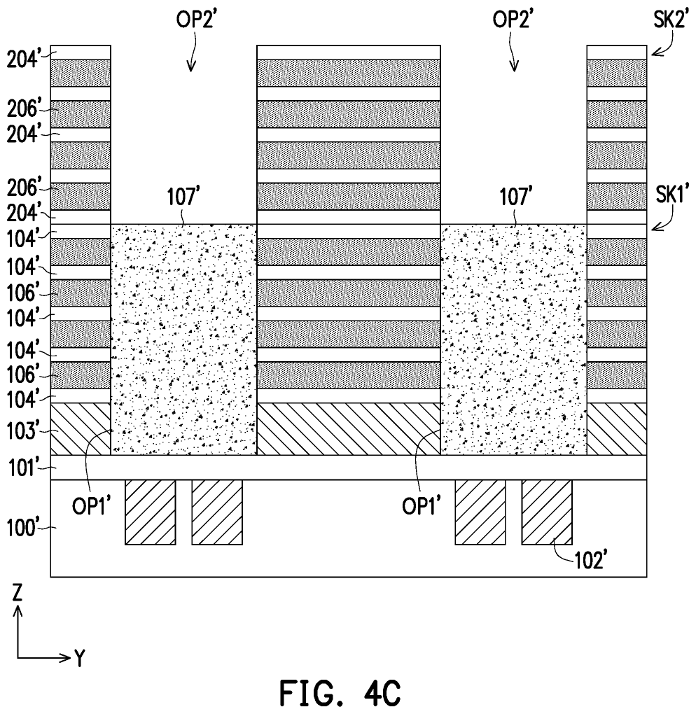

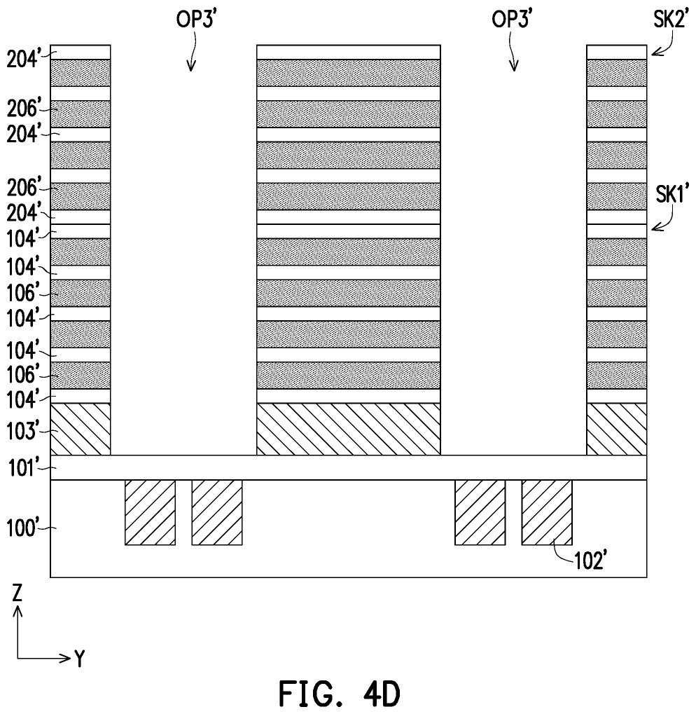

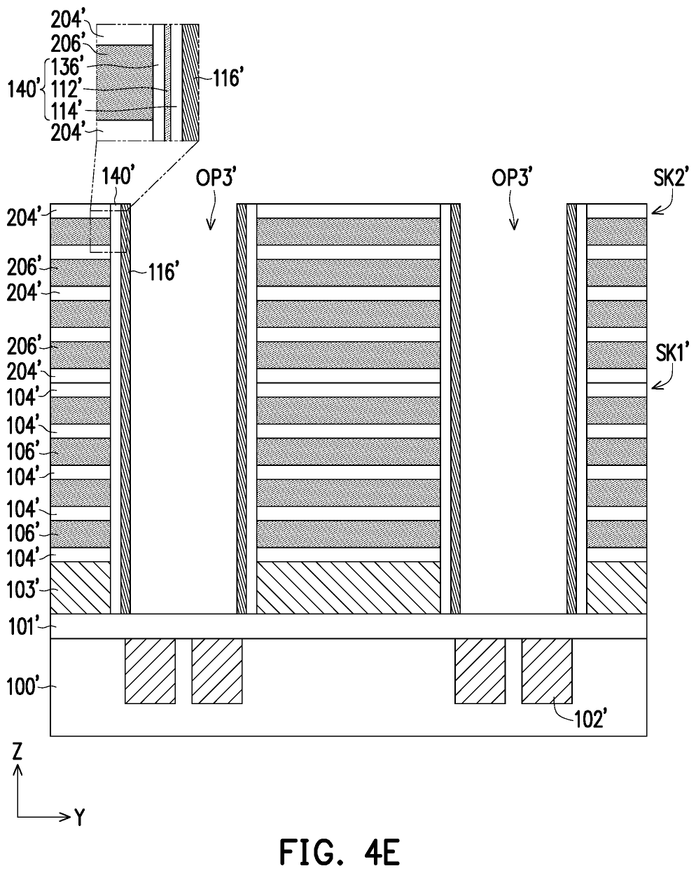

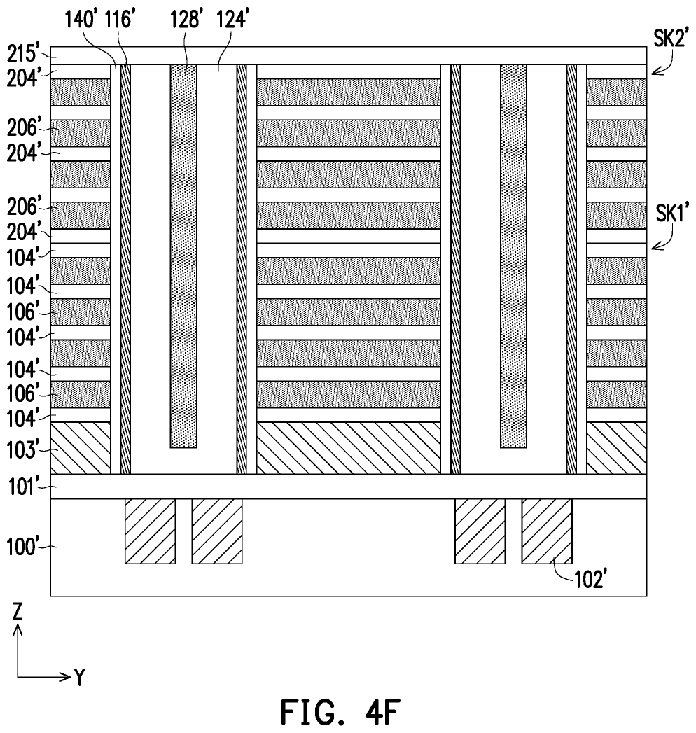

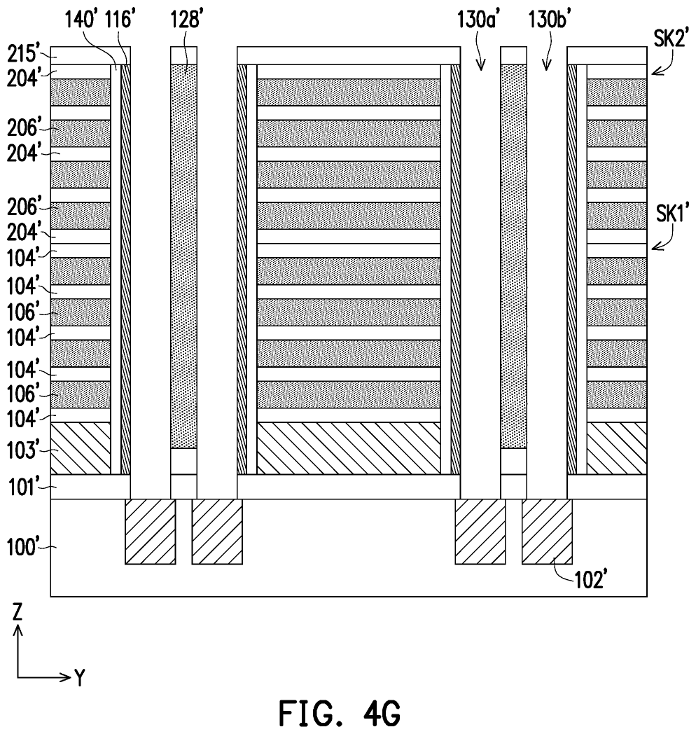

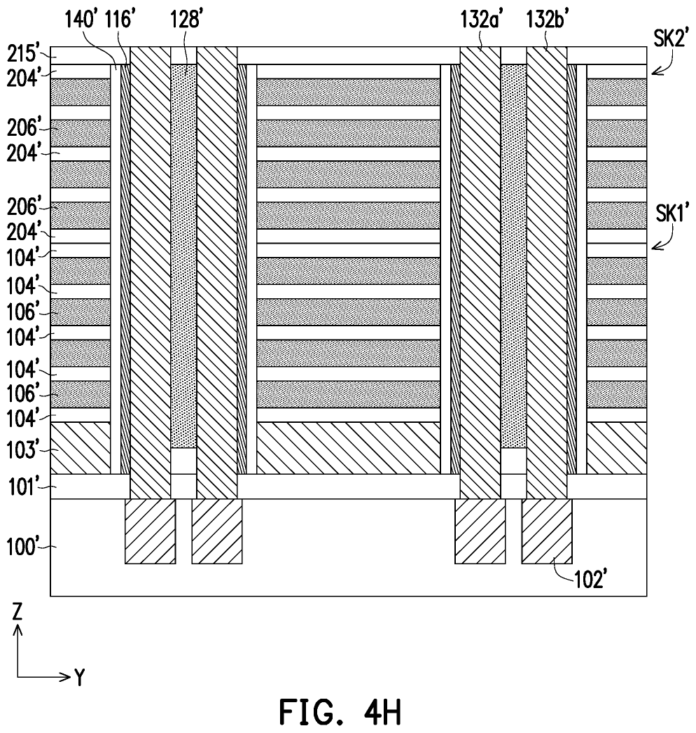

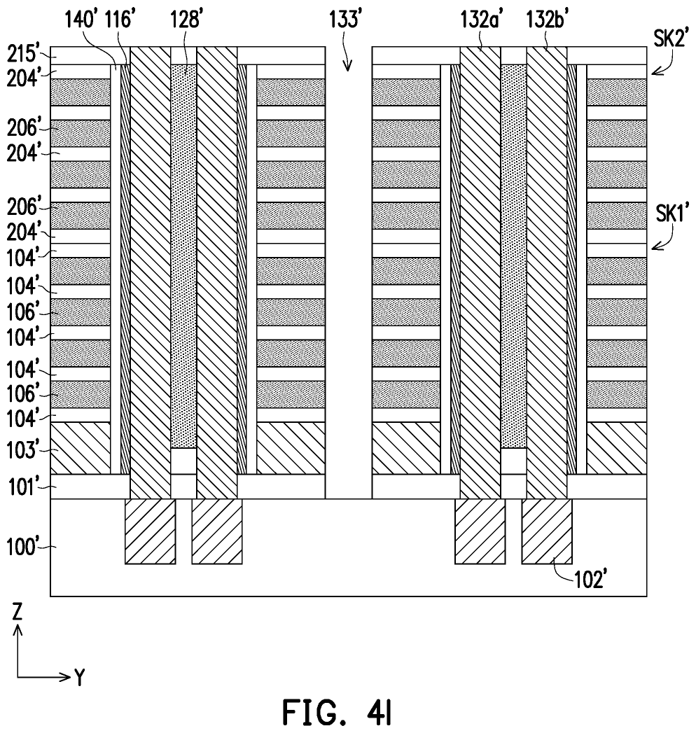

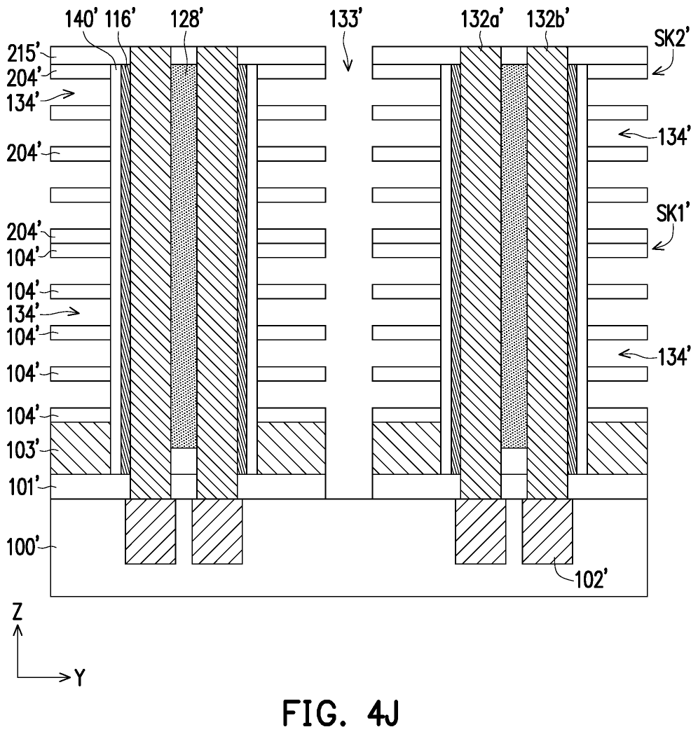

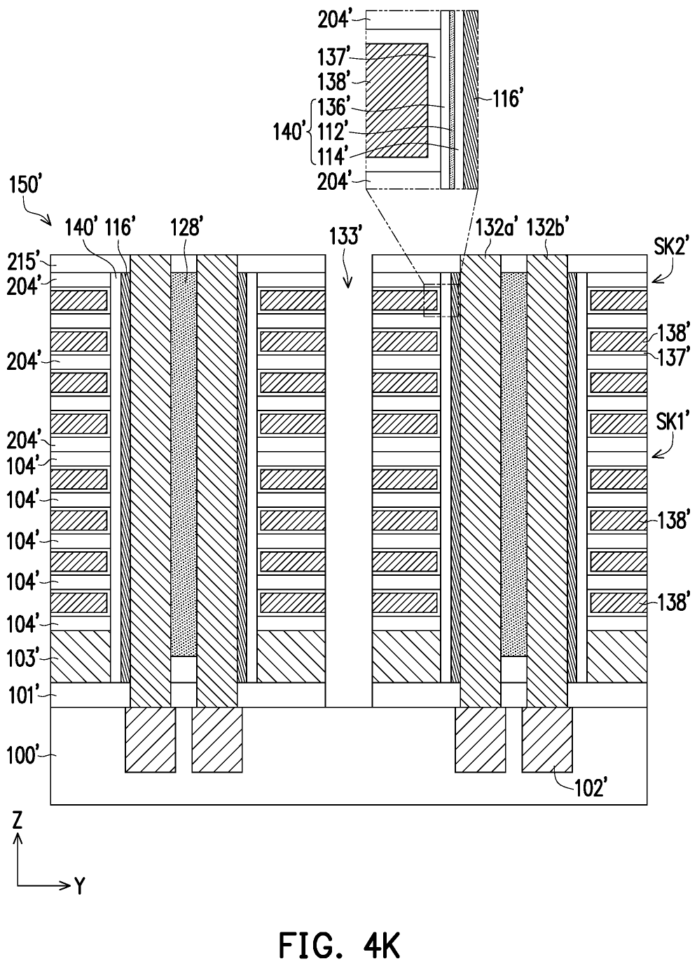

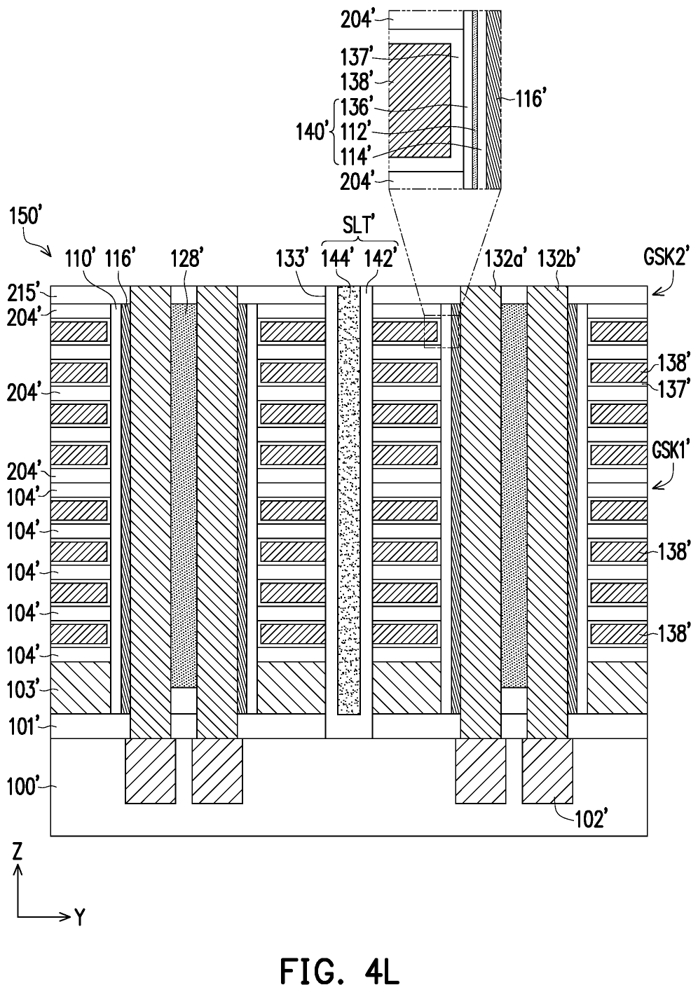

FIG. 4A to FIG. 4L show schematic cross-sectional views of a process of fabricating a memory device according to an embodiment of the disclosure.

Referring to FIG. 4A, an insulating layer 101′, a stop layer 102′, and a semiconductor layer 103′ are formed on a dielectric substrate 100′. The insulating layer 101′, the stop layer 102′, and the semiconductor layer 103′ may be the same as or similar to the insulating layer 101, the stop layer 102, and the semiconductor layer 103. Next, a stack structure SK1′ is formed on the semiconductor layer 103′. The stack structure SK1′ is composed of insulating layers 104′ and intermediate layers 106′ that are sequentially alternately stacked on the dielectric substrate 100′. The dielectric substrate 100′, the insulating layer 104′ and the intermediate layer 106′ of the stack structure SK1′ may be the same as or similar to the dielectric substrate 100, the insulating layer 104 and the intermediate layer 106 of the stack structure SK1.

Afterwards, lithography and etching processes are performed to form a plurality of openings OP1′ in the stack structure SK1′. The opening OP1′ extends through the semiconductor layer 103′, and the bottom surface of the opening OP1′ does not expose the stop layer 102′, but the disclosure is not limited thereto. In this embodiment, in a top view, the opening OP1′ has a circular profile (not shown), but the disclosure is not limited thereto. In other embodiments, the opening OP1′ may have a profile of other shapes such as a polygonal shape (not shown).

Referring to FIG. 4B, in this embodiment, a sacrificial plug 107′ is filled in the opening OP1′. The material of the sacrificial plug 107′ is different from the material of the insulating layer 104′ and is also different from the material of the intermediate layer 106′. The material of the sacrificial plug 107′ is, for example, a carbon-containing organic material. The carbon-containing organic material may be a polymer such as a photoresist. The photoresist may be a positive photoresist or a negative photoresist. The forming method of the sacrificial plug 107′ is, for example, a spin coating method. The material of the sacrificial plug 107′ is not limited thereto, and another material may also be used.

Referring to FIG. 4B, a stack structure SK2′ is formed on the stack structure SK1′. The stack structure SK2′ may also be referred to as an insulating stack structure SK2′. In this embodiment, the stack structure SK2′ may be composed of insulating layers 204′ and intermediate layers 206′ that are sequentially alternately stacked with each other. The materials of the insulating layer 204′ and the intermediate layer 206′ may be the same as or similar to the materials of the insulating layer 104′ and the intermediate layer 106′, respectively.

Referring to FIG. 4C, lithography and etching processes are performed to form a plurality of openings OP2′ in the stack structure SK2′. The shape and depth of the opening OP2′ may be the same as or similar to those of the opening OP1′. During the etching process, the sacrificial plug 107′ may serve as an etch stop layer. Therefore, the formed opening OP2′ extends from the stack structure SK2′ until the sacrificial plug 107′ is exposed.

Referring to FIG. 4D, the sacrificial plug 107′ is removed so that the opening OP2′ communicates with the opening OP1′ to form an extended opening OP3′. The extended opening OP3′ extends from the stack structure SK2′ through the stack structure SK1′ and the semiconductor layer 103′ and exposes the insulating layer 101′. The method of removing the sacrificial plug 107′ may use a dry removal method or a wet removal method. When the material of the sacrificial plug 107′ is a carbon-containing organic material, a dry removal method such as an oxygen plasma ashing method may be adopted to remove the sacrificial plug 107′ without issues of over-etching or insufficient etching depth (openness) of the opening OP2′.

Referring to FIG. 4E, a charge storage structure 140′ and a channel pillar 116′ are formed in the opening OP3′. The charge storage structure 140′ includes a tunneling layer 114′, a charge storage layer 112′, and a blocking layer 136′. The materials and forming methods of the tunneling layer 114′, the charge storage layer 112′, and the blocking layer 136′ are the same as or similar to the material and forming method of the tunneling layer 114, the charge storage layer 112, and the blocking layer 136. The materials and forming method of the channel pillar 116′ is the same as or similar to the material and forming method of the channel pillar 116.

Referring to FIG. 4F, an insulating filling layer 124′ and an insulating pillar 128′ are formed in the opening OP3′. Afterwards, a cap insulating layer 215′ is formed on the stack structure SK2′. The materials and forming methods of the insulating filling layer 124′, the insulating pillar 128′, and the cap insulating layer 215′ are the same as or similar to the materials and forming methods of the insulating filling layer 124, the insulating pillar 128, and the cap insulating layer 215.

Referring to FIG. 4G, a patterning process (e.g., lithography and etching processes) is performed to form holes 130a′ and 130b′ in the cap insulating layer 215′ and the insulating filling layer 124′. During the etching process, the stop layer 102′ may serve as an etch stop layer.

Referring to FIG. 4H, conductive pillars 132a′ and 132b′ are formed in the holes 130a′ and 130b′. The conductive pillars 132a′ and 132b′ may respectively serve as a source pillar and a drain pillar to be each electrically connected to the channel pillar 116′. The materials and forming methods of the conductive pillars 132a′ and 132b′ are the same as or similar to the materials and forming methods of the conductive pillars 132a and 132b.

Referring to FIG. 4I, a patterning process (e.g., lithography and etching processes) is performed on the cap insulating layer 215′, the stack structure SK2′, the stack structure SK1′, and the semiconductor layer 103′ to form a slit trench 133′. During the etching process, the insulating layer 101′ or the semiconductor layer 103′ may serve as an etch stop layer, so that the insulating layer 101′ or the semiconductor layer 103′ is exposed at the bottom of the slit trench 133′. The slit trench 133′ may also extend to the insulating layer 101′ to expose the dielectric substrate 100′.

Referring to FIG. 4J to FIG. 4K, a partial replacement process is performed on the intermediate layers 206′ and 106′. First, an etching process is performed to remove most of the intermediate layers 206′ and 106′ to form a plurality of horizontal openings 134′. Next, a plurality of barrier layers 137′, and a plurality of gate layers (also referred to as conductive layers) 138′ are formed in the horizontal openings 134′. The materials and forming methods of the barrier layer 137′, and the gate layer 138′ may be the same as or similar to the materials and forming methods of the barrier layer 137, and the gate layer 138.

Referring to FIG. 4K and FIG. 4L, a slit SLT′ is formed in the slit trench 133′. The slit SLT′ includes, for example, a liner layer 142′ and a conductive layer 144′. The materials and forming methods of the liner layer 142′ and the conductive layer 144′ are the same as or similar to the materials and forming methods of the liner layer 142 and the conductive layer 144. In other embodiments, the slit SLT′ may also be completely filled with an insulating material without any conductive layer. In still other embodiments, the slit SLT′ may also be a liner layer 142′, and the liner layer 142′ covers an air gap without any conductive layer.

Afterwards, a contact (not shown) is formed in the staircase region. The contact lands on the end of the gate layer 138′ in the staircase region and is electrically connected thereto.

FIG. 6C shows a partial perspective view of FIG. 4L.

Referring to FIG. 4L and FIG. 6C, the memory device of the disclosure includes the stack structures GSK1′ and GSK2′, the channel pillar 116′, the conductive pillars 132a′ and 132b′, and the charge storage structure 140′. The stack structure GSK1′ is located above the dielectric substrate 100′ and includes a plurality of conductive layers 138′ and a plurality of insulating layers 104′ alternating with each other. The stack structure GSK2′ is located on the stack structure GSK1′, and the stack structure GSK2′ includes a plurality of conductive layers 138′ and a plurality of insulating layers 204′ alternating with each other. The channel pillar 116′ and the conductive pillars 132a′ and 132b′ extend through the stack structures GSK2′ and GSK1′. The charge storage structure 140′ is located between the channel pillar 116′ and the conductive layer 138′.

In this embodiment, the opening OP2′ (shown in FIG. 4C) is completely aligned with the opening OP1′ (shown in FIG. 4A), and the holes 130a′ and 130b′ (shown in FIG. 4G) are formed through a single lithography and etching process. Therefore, the channel pillar 116′ continuously extends through the stack structures GSK2′ and GSK1′. The sidewall of a portion P2′ of the channel pillar 116′ around the stack structure GSK2′ is completely aligned with the sidewall of a portion P1′ of the channel pillar 116′ around the stack structure GSK1′ without turning.

The conductive pillars 132a′ and 132b′ are continuous pillars which continuously extend through the channel pillar 116′ and are electrically connected to the channel pillar 116′. Moreover, complete crystal grains are present between the conductive pillars 132a′ and 132b′ around the stack structure GSK2′ and the conductive pillars 132a′ and 132b′ around the stack structure GSK1′, and there is no planar interface formed with etched or polished crystal grains. Likewise, the sidewalls of the conductive pillars 132a′ and 132b′ around the stack structure GSK2′ are substantially aligned with the sidewalls of the conductive pillars 132a′ and 132b′ around the stack structure GSK1′ without turning.

Referring to FIG. 4L, the memory device of the disclosure further includes the insulating pillar 128′ located between the conductive pillars 132a′ and 132b′. The insulating pillar 128′ around the stack structure GSK2′ is exactly aligned with and overlaps the insulating pillar 128′ around the stack structure GSK1′.

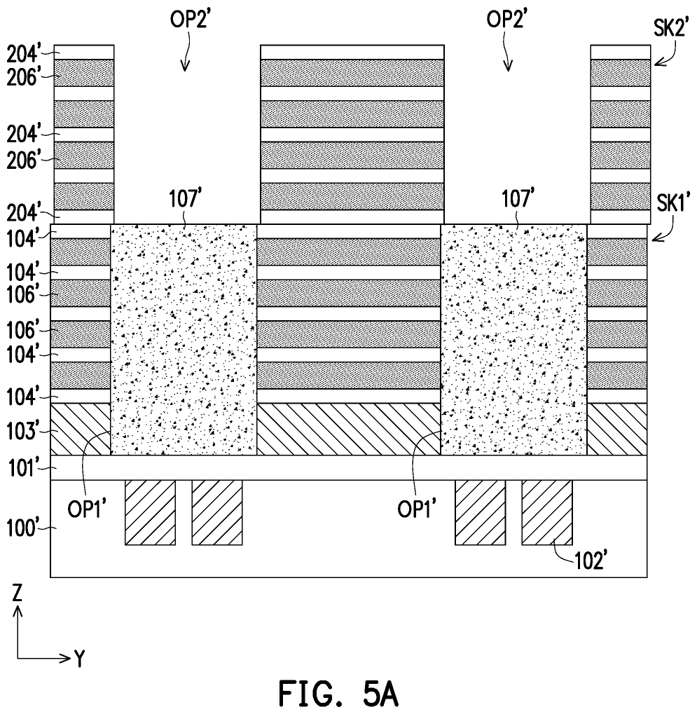

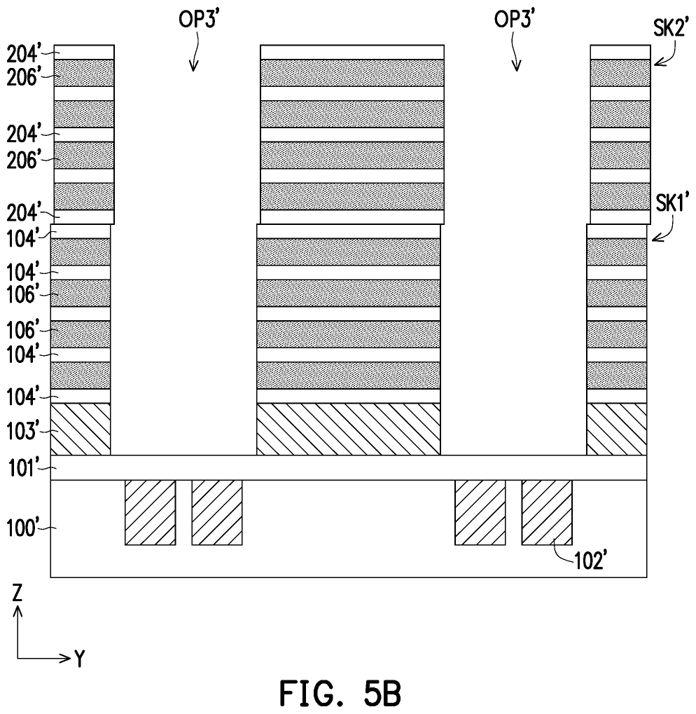

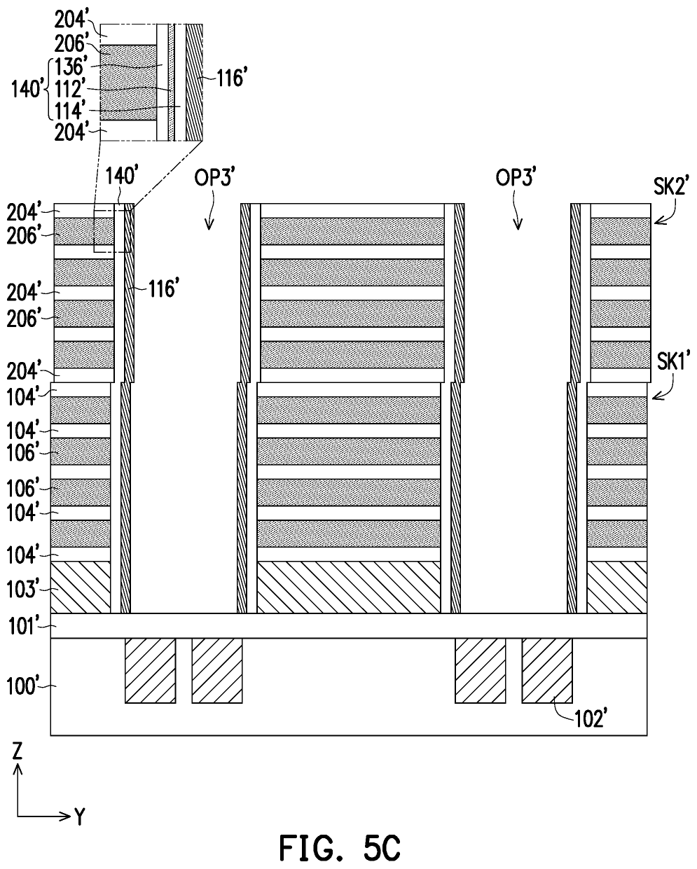

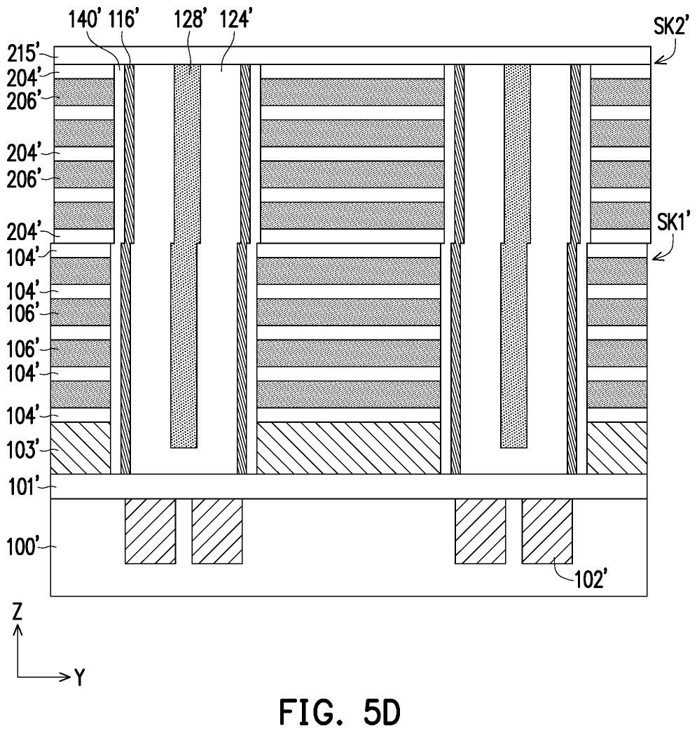

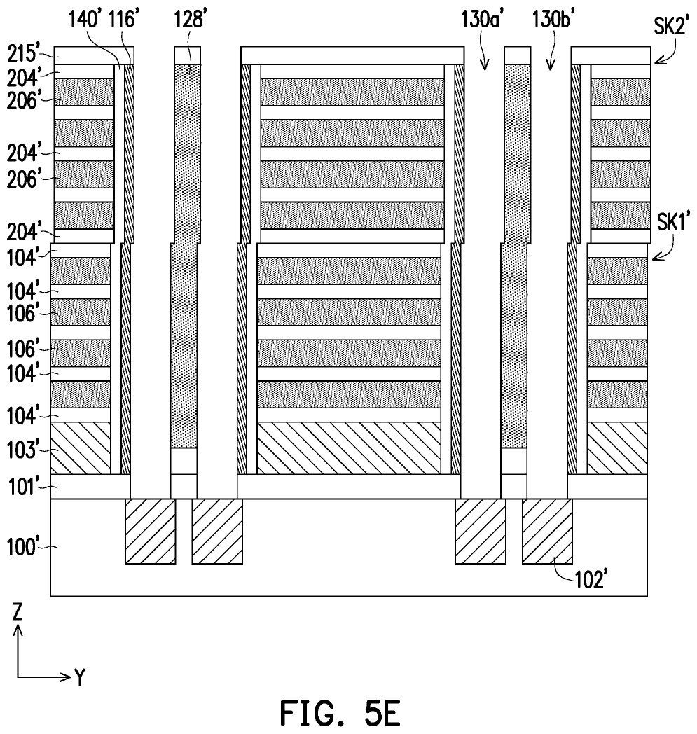

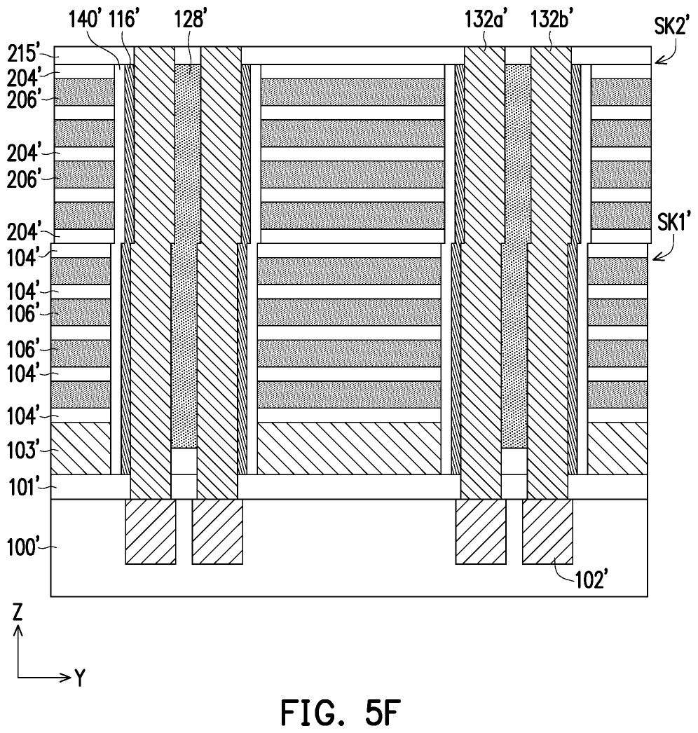

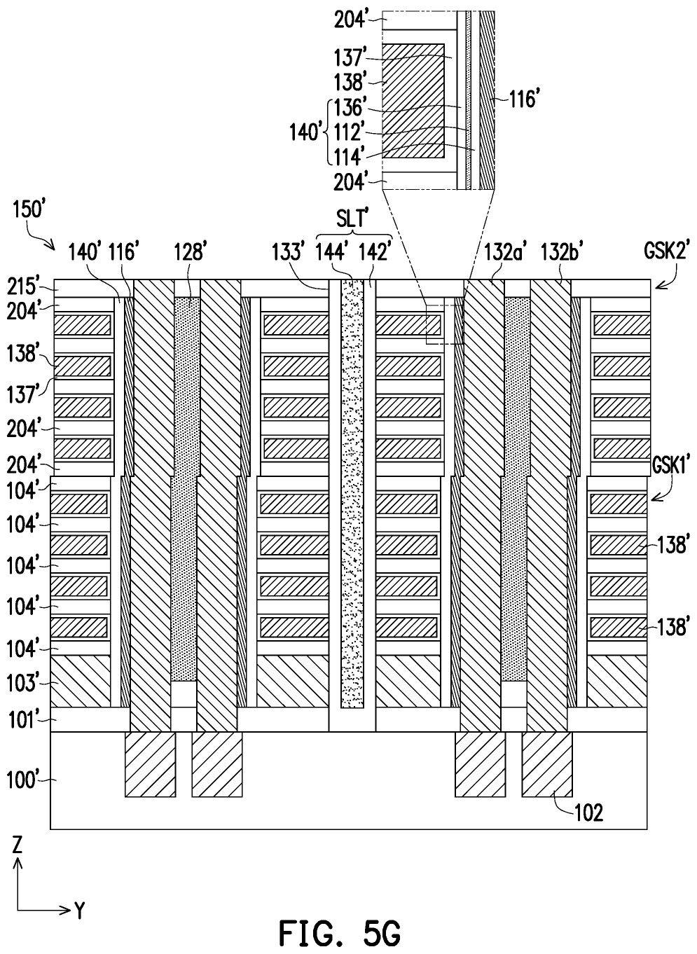

FIG. 5A to FIG. 5G show schematic cross-sectional views of a process of fabricating a memory device with misalignment according to another embodiment of the disclosure.

Referring to FIG. 5A to FIG. 5B, in some cases, misalignment occurs when the opening OP2′ is formed (as shown in FIG. 5A); as a result, the sacrificial plug 107′ is not completely exposed by the opening OP2′. However, since the sacrificial plug 107′ may be removed by the oxygen plasma ashing method, the sacrificial plug 107′ may be completely removed to form an opening OP3′ extending through the stack structures SK2‘ and SK1’ (as shown in FIG. 5B).

Referring to FIG. 5C, subsequently, the charge storage structure 140′ and the channel pillar 116′ are formed in the opening OP3′. Next, the insulating filling layer 124′ and the insulating pillar 128′ are formed in the opening OP3′, and the cap insulating layer 215′ is formed on the stack structure SK2′.

Referring to FIG. 5E, a patterning process (e.g., lithography and etching processes) is performed to form the holes 130a′ and 130b′ in the cap insulating layer 215′ and the insulating filling layer 124′.

Referring to FIG. 5F, the conductive pillars 132a′ and 132b′ are formed in the holes 130a′ and 130b′.

Referring to FIG. 5G, a patterning process (e.g., lithography and etching processes) is performed on the cap insulating layer 215′, the stack structure SK2′, the stack structure SK1′, and the semiconductor layer 103′ to form a slit trench 133′. Next, the intermediate layers 206′ and 106′ are replaced with a plurality of barrier layers 137′, and a plurality of gate layers 138′. Afterwards, a slit SLT′ is formed in the slit trench 133′.

FIG. 6D shows a partial perspective view of FIG. 5G. Referring to FIG. 5G and FIG. 6D, the memory device of the disclosure includes the stack structures GSK1′ and GSK2′, the channel pillar 116′, the conductive pillars 132a′ and 132b′, and the charge storage structure 140′. The stack structure GSK1′ is located above the dielectric substrate 100′ and includes a plurality of conductive layers 138′ and a plurality of insulating layers 104′ alternating with each other. The stack structure GSK2′ is located on the stack structure GSK1′, and the stack structure GSK2′ includes a plurality of conductive layers 138′ and a plurality of insulating layers 204′ alternating with each other. The channel pillar 116′ and the conductive pillars 132a′ and 132b′ extend through the stack structures GSK2′ and GSK1′. The charge storage structure 140′ is located between the channel pillar 116′ and the conductive layer 138′.

In this embodiment, the opening OP2′ is not completely aligned with the opening OP1′, so the sidewall of the extended opening OP3′ as formed has a turning. The channel pillar 116′ formed on the sidewall of the extended opening OP3′ continuously extends through the stack structures GSK2′ and GSK1′, but the sidewall of a portion P2′ of the channel pillar 116′ around the stack structure GSK2′ is not completely aligned with the sidewall of a portion P1′ of the channel pillar 116′ around the stack structure GSK1′ and thus a turning T2′ is present.

Likewise, since the sidewall of the channel pillar 116′ has a turning T1′, in some embodiments, the sidewalls of the holes 130a′ and 130b′ exposing the channel pillar 116′ also have turnings. Therefore, the conductive pillars 132a′ and 132b′ may be each divided into two segments S1′ and S2′. The segment S1′ is surrounded by the stack structure GSK1′ and the segment S2′ is surrounded by the stack structure GSK2′. The segment S2′ is partially overlapping and partially non-overlapping with the segment S1′. In other words, a centerline C2′ of the segment S2′ is not aligned with a centerline C1′ of the segment S1′, and a non-zero distance d1′ is present therebetween. The sidewall of the segment S2′ is not aligned with the sidewall of segment S1′ and thus a turning T1′ is present.

However, since the conductive pillars 132a′ and 132b′ are formed in the holes 130a′ and 130b′, they are continuous pillars extending continuously through the channel pillar 116′ and electrically connected to the channel pillar 116′. Furthermore, complete crystal grains are present between the segment S2′ and the segment S1′, and there is no planar interface formed with etched or polished crystal grains.

The above embodiments have been described with two stack structures, but the disclosure may be applied to a memory device with more stack structures. In addition, the above embodiments have been described with a 3D AND flash memory. However, the embodiments of the disclosure are not limited thereto, and the embodiments of the disclosure may also be applied to a 3D NOR flash memory or a 3D NAND flash memory.

Based on the above, in the memory device according to the embodiments of the disclosure, the stack structure is formed in a plurality of parts, which can reduce the aspect ratio of the openings or holes formed in the stack structure and thus reduce the difficulty of the process. In addition, in the disclosure, the sacrificial plugs or sacrificial pillars are formed in the first-formed openings or holes, and these sacrificial plugs or sacrificial pillars can be easily removed after the upper openings or the upper holes are formed to thereby form openings or holes having a high aspect ratio extending through the stack structure. Therefore, the disclosure can simplify the fabrication process and can be integrated with the existing fabrication process to increase the degree of integration, increase the fabrication process yield, and reduce the fabrication cost.

What is claimed is:

1. A memory device comprising:
a first stack structure located above a dielectric substrate and comprising a plurality of first conductive layers and a plurality of first insulating layers alternating with each other;
a first channel pillar passing through the first stack structure;
a second stack structure located on the first stack structure, the second stack structure comprising a plurality of second conductive layers and a plurality of second insulating layers alternating with each other;
a second channel pillar passing through the second stack structure and separated from the first channel pillar;
a first conductive pillar and a second conductive pillar each electrically connected to the first channel pillar and the second channel pillar; and
a plurality of charge storage structures located between the first channel pillar and the first conductive layer and between the second channel pillar and the second conductive layer.

2. The memory device according to claim 1, wherein the first conductive pillar and the second conductive pillar are continuous pillars.

3. The memory device according to claim 1, wherein sidewalls of the first conductive pillar and the second conductive pillar have turnings.

4. The memory device according to claim 1, wherein the first conductive pillar and the second conductive pillar each comprise:
a first segment extending through the first stack structure; and
a second segment connected to the first segment and extending through the second stack structure, wherein a non-zero distance is present between a centerline of the first segment a centerline of the second segment.

5. The memory device according to claim 1, further comprising:
a first semiconductor layer located between the dielectric substrate and the first stack structure; and
a second semiconductor layer located between the first stack structure and the second stack structure.

6. The memory device according to claim 1, further comprising:
a first insulating pillar extending through the first stack structure and interposed between the first conductive pillar and the second conductive pillar; and
a second insulating pillar extending through the second stack structure and interposed between the first conductive pillar and the second conductive pillar, wherein the first insulating pillar and the second insulating pillar are separated from each other.

7. The memory device according to claim 1, further comprising:
a plurality of protection layers separating the plurality of charge storages.

8. A memory device comprising:
a first stack structure on a dielectric substrate, and comprising a plurality of first conductive layers and a plurality of first insulating layers alternating with each other;
a second stack structure located on the first stack structure, the second stack structure comprising a plurality of second conductive layers and a plurality of second insulating layers alternating with each other;
a channel pillar comprising:
a first portion extending through the first stack structure; and
a second portion connected to the first portion and extending through the second stack structure;
a first conductive pillar and a second conductive pillar extending through the channel pillar and electrically connected to the channel pillar; and
a charge storage structure located between the channel pillar and the first conductive layer and between the channel pillar and the second conductive layer.

9. The memory device according to claim 8, wherein a turning is present in a sidewall of the first conductive pillar and a sidewall of the second conductive pillar.

10. The memory device according to claim 8, wherein the first conductive pillar and the second conductive pillar are continuous pillars.

11. The memory device according to claim 8, further comprising an insulating pillar which extends through the second stack structure and the first stack structure and is interposed between the first conductive pillar and the second conductive pillar.

12. The memory device according to claim 8, further comprising:
a semiconductor layer located between the dielectric substrate and the first stack structure.

13. A method of fabricating a memory device, comprising:
forming a first stack structure on a dielectric substrate, the first stack structure comprising a plurality of first intermediate layers and a plurality of first insulating layers alternating with each other;
forming a first opening in the first stack structure;
forming a first channel pillar on a sidewall of the first opening;
forming a first sacrificial pillar and a second sacrificial pillar in the first channel pillar;
forming a second stack structure on the first stack structure, the second stack structure comprising a plurality of second intermediate layers and a plurality of second insulating layers alternating with each other;
forming a second opening in the second stack structure;
forming a second channel pillar in the second opening;
forming an insulating filling layer in the second channel pillar;
forming a first hole and a second hole in the insulating filling layer, wherein the first hole and the second hole respectively expose the first sacrificial pillar and the second sacrificial pillar;
removing the first sacrificial pillar and the second sacrificial pillar to form a first extending hole and a second extending hole extending through the second stack structure and the first stack structure;
forming a first conductive pillar and a second conductive pillar in the first extending hole and the second extending hole;
replacing the plurality of first intermediate layers and the plurality of second intermediate layers with a plurality of conductive layers; and
forming a plurality of charge storage structures between the first channel pillar and the plurality of conductive layers and between the second channel pillar and the plurality of conductive layers.

14. The method of fabricating a memory device according to claim 13, wherein the forming the first sacrificial pillar and the second sacrificial pillar comprises:
forming a first an insulating filling layer in the first channel pillar, wherein a seam is left at the center of the insulating filling layer;
forming a first insulating pillar in the seam;
forming a third hole and a fourth hole in the first insulating filling layer, wherein the thirst hole and the third hole respectively expose the first channel pillar and the first insulating pillar;
forming the first sacrificial pillar and the second sacrificial pillar in the third hole and the fourth hole respectively.

15. The method of fabricating a memory device according to claim 14, further comprising:
forming a first semiconductor layer located between the dielectric substrate and the first stack structure; and
forming a second semiconductor layer located between the first stack structure and the second stack structure.

16. The method of fabricating a memory device according to claim 15, further comprising:
forming an etching stop layer in the dielectric substrate, and the first sacrificial pillar and the second sacrificial pillar land on the etching stop layer.

17. The method of fabricating a memory device according to claim 13, further comprising:
forming a second insulating pillar in the second pillar.

18. The method of fabricating a memory device according to claim 17, wherein the first hole and the second hole exposes the second channel pillar and the second insulating pillar.

19. The method of fabricating a memory device according to claim 17, further comprising:
forming a first protection layer on the sidewall of the first opening, wherein the first protection layer is located between the first channel pillar and the plurality of first insulating layers, and between the first channel pillar and the plurality of first intermediate layers; and
forming a second protection layer on the sidewall of the second opening, wherein the second protection layer is located between the second channel pillar and the plurality of second insulating layers, and between the second channel pillar and the plurality of second intermediate layers.

20. The method of fabricating a memory device according to claim 19, further comprising:
removing a portion of the first protection layer between the first channel pillar and the plurality of first intermediate layers; and
removing a portion of the second protection layer between the second channel pillar and the plurality of second intermediate layers.
